(19) United States
(12) Patent Application Publication
(10) Pub. No.: US 2023/0099077 A1
(43) Pub. Date: Mar. 30, 2023

(54) MIST GENERATOR, THIN FILM MANUFACTURING DEVICE, AND THIN FILM MANUFACTURING METHOD

(71) Applicant: NIKON CORPORATION, Tokyo (JP)

(72) Inventors: Ryoko SUZUKI, Yokohama-shi (JP); Yasutaka NISHI, Tokyo (JP); Kotaro OKUI, Hachioji-shi (JP)

(73) Assignee: NIKON CORPORATION, Tokyo (JP)

(21) Appl. No.: 18/073,822

(22) Filed: Dec. 2, 2022

Related U.S. Application Data
(63) Continuation of application No. PCT/JP2021/020399, filed on May 28, 2021.

(30) Foreign Application Priority Data
Jun. 2, 2020 (JP) 2020-096341

(51) Int. Cl. H05H 1/48; C23C 16/448; C23C 16/50; B05B 17/06

(52) U.S. Cl. CPC H05H 1/48; C23C 16/448; C23C 16/50; B05B 17/0615; H05H 2245/42

(57) ABSTRACT

Provided is a mist generator including: a container that stores a liquid; a gas supply unit that supplies a gas into the container; and an electrode that generates plasma of the gas between the electrode and the liquid, where the supply direction of the gas fed from the gas supply opening of the gas supply unit is different from a direction in which gravity acts.

### CROSS REFERENCE TO RELATED APPLICATIONS

This application is a continuation of International Patent Application No. PCT/JP2021/020399 filed on May 28, 2021, which claims priority benefit from Japanese Patent Application No. 2020-096341 filed on Jun. 2, 2020, the contents of which are incorporated herein by reference.

### TECHNICAL FIELD

The present invention relates to a mist generator, a thin film manufacturing device, and a thin film manufacturing method.

### BACKGROUND ART

Conventionally, such a vapor deposition method as presented in Patent Literature 1 is used as a technique for fabricating a thin film on a substrate. In general, in film formation steps, techniques that require a vacuum or a depressurized environment, such as a sputtering method, are used in addition to vapor deposition methods. Thus, the devices are problematically increased in size and expensive.

### CITATION LIST

### Patent Literature

Patent Literature 1: JP 2010-265508 A

### SUMMARY OF INVENTION

A first aspect of the present invention is a mist generator including: a container that stores a liquid; a gas supply unit that supplies a first gas from a gas supply opening into the container; and an electrode that generates plasma between the electrode and the liquid, where the supply direction of the first gas fed from the gas supply opening of the gas supply unit is different from a direction in which gravity acts.

A second aspect of the present invention is a mist generator including: a container that stores a liquid; a gas supply unit that supplies a first gas from a gas supply opening into the container; and an electrode that generates plasma between the electrode and the liquid, where the gas supply opening of the gas supply unit does not face a liquid level.

A third aspect of the present invention is a mist generator including: a container that stores a liquid; a gas supply unit that supplies a first gas from a gas supply opening into the container; and a plasma generation unit including an electrode that generates plasma between the electrode and a liquid level of the liquid, and a hollow body surrounding the electrode, where one tip of the hollow body is located below the liquid level of the liquid.

A fourth aspect of the present invention is a thin film manufacturing device for forming a film on a substrate, including: the device according to any one of the first to third aspects; and a mist supply unit that supplies the liquid turned into a mist onto a predetermined substrate.

A fifth aspect of the present invention is a thin film manufacturing method for forming a film on a substrate, including: a step of using the device according to any one of the first to third aspects to turn the liquid into a mist; and a step of supplying the liquid turned into the mist to a predetermined substrate.

### BRIEF DESCRIPTION OF DRAWINGS

FIG. 1 is a schematic diagram illustrating an example of a mist generator according to a first embodiment.

FIG. 2A is a schematic diagram illustrating an example of a tip 79 of an electrode 78 according to the first embodiment. FIG. 2A is an example of an electrode 78A with a tip 79A in a needle shape.

FIG. 2B is a schematic diagram illustrating an example of the tip 79 of the electrode 78 according to the first embodiment. FIG. 2B is an example of an electrode 78B with a plurality of needle-shaped parts for a tip 79B.

FIG. 2C is a schematic diagram illustrating an example of the tip 79 of the electrode 78 according to the first embodiment. FIG. 2C is an example of an electrode 78C with a tip 79C in a spherical shape.

FIG. 3A is an explanatory diagram showing an example of a supply direction and the angle θ made by the supply direction and the direction of gravitational force. FIG. 3A is a schematic diagram showing an example of a gas supply unit according to the first embodiment and illustrating the supply direction.

FIG. 3B is an explanatory diagram showing an example of the supply direction and the angle θ made by the supply direction and the direction of gravitational force. FIG. 3B is a schematic diagram illustrating the supply direction of a gas supply unit 70B.

FIG. 3C is an explanatory diagram showing an example of the supply direction and the angle θ made by the supply direction and the direction of gravitational force. FIG. 3C is a diagram for illustrating the angle θ in FIG. 3A.

FIG. 4A is an explanatory diagram showing an example of a discharge direction and the angle α made by the discharge direction and the direction of gravitational force. FIG. 4A is a schematic diagram showing an example of a discharge unit 74A according to the first embodiment and illustrating the discharge direction.

FIG. 4B is an explanatory diagram showing an example of the discharge direction and the angle α made by the discharge direction and the direction of gravitational force. FIG. 4B is a schematic diagram illustrating the discharge direction of a discharge unit 74B.

FIG. 4C is an explanatory diagram showing an example of the discharge direction and the angle α made by the discharge direction and the direction of gravitational force. FIG. 4C is a diagram for illustrating the angle α.

FIG. 5A is an explanatory diagram showing an example of the angle D made by a supply direction and a discharge direction. FIG. 5A is a schematic diagram of a gas supply unit 70C and a discharge unit 74C according to the first embodiment.

FIG. 5B is an explanatory diagram showing an example of the angle β made by the supply direction and the discharge direction. FIG. 5B is a diagram for illustrating the angle β.

FIG. 6 is a schematic diagram showing an example of a mist generator according to Modification Example 1 of the first embodiment.

FIG. 7 is a schematic diagram showing an example of a mist generator according to Modification Example 2 of the first embodiment.

FIG. 8 is a schematic diagram showing an example of a mist generator according to Modification Example 3 of the first embodiment.

FIG. 9 is a schematic diagram showing an example of a mist generator according to Modification Example 4 of the first embodiment.

FIG. 10 is a schematic diagram showing an example of a mist generator according to Modification Example 5 of the first embodiment.

FIG. 11 is a schematic diagram showing an example of a mist generator according to a second embodiment.

FIG. 12 is a schematic diagram showing an example of a mist generator according to a third embodiment.

FIG. 13 is a schematic diagram showing a modification example of the mist generator according to the third embodiment.

FIG. 14 is a schematic diagram showing an example of a mist generator according to a fourth embodiment.

FIG. 15 is a schematic diagram showing an example of a mist generator according to a fifth embodiment.

FIG. 16 is a schematic diagram showing a modification example of the mist generator according to the fifth embodiment.

FIG. 17 is a schematic diagram showing an example of a mist generator according to a sixth embodiment.

FIG. 18 is a schematic diagram showing a modification example of the mist generator according to the sixth embodiment.

FIG. 19 is a diagram showing a configuration example of a thin film manufacturing device according to a seventh embodiment.

FIG. 20 is an example of a perspective view of a mist supply unit as viewed from the substrate side.

FIG. 21 is an example of a cross-sectional view of a tip of the mist supply unit and a pair of electrodes as viewed from the Y-axis direction.

FIG. 22 is a block diagram showing an example of a schematic configuration of a high-voltage pulse power supply unit.

FIG. 23 is a diagram showing an example of waveform characteristics of an inter-electrode voltage obtained in the high-voltage pulse power supply unit.

FIG. 24 is a cross-sectional view showing an example of a configuration example of a substrate temperature control unit.

FIG. 25 is a schematic diagram showing an example of a mist generator according to an eighth embodiment.

FIG. 26A is a diagram for illustrating an outline of a plasma generation unit. FIG. 26A is an example of the appearance of a tip part of the plasma generation unit.

FIG. 26B is a diagram for illustrating an outline of the plasma generation unit. FIG. 26B is an example (part 1) of a cross-sectional view (top view) of the plasma generation unit.

FIG. 26C is a diagram for illustrating an outline of the plasma generation unit. FIG. 26C is an example (part 2) of a cross-sectional view (top view) of the plasma generation unit.

FIG. 27 is a schematic diagram showing an example of a mist generator according to Modification Example 1 of the eighth embodiment.

FIG. 28 is a schematic diagram showing an example of a mist generator according to Modification Example 2 of the eighth embodiment.

FIG. 29 is a schematic diagram showing an example of a mist generator according to Modification Example 3 of the eighth embodiment.

### DESCRIPTION OF EMBODIMENTS

Hereinafter, preferred embodiments of a mist generator 90 according to a mode for carrying out the present invention (hereinafter referred to as “the present embodiment”), a thin film manufacturing device 1 including the mist generator 90, and a thin film manufacturing method for fabricating a thin film with the use of the mist generator 90 will be set forth, and described in detail with reference to the accompanying drawings. The following embodiments are considered for explaining the present invention, and not intended to limit the present invention to the following description. It is to be noted that, in the drawings, positional relationships such as up, down, left, and right are based on the positional relationships illustrated in the drawings, unless otherwise specified. Furthermore, the dimensional ratios in the drawings are not to be considered limited to the illustrated ratios.

### First Embodiment

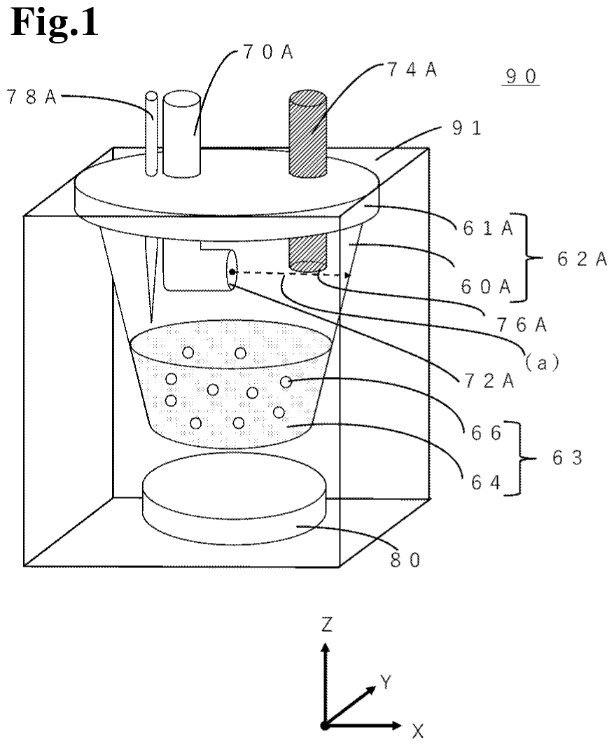

FIG. 1 is a schematic diagram illustrating an example of a mist generator 90 for generating a mist according to a first embodiment. It is to be noted that in the following description, an XYZ orthogonal coordinate system is set, where an X-axis direction, a Y-axis direction, and a Z-axis direction are set in accordance with the arrows shown in the drawings.

<Mist Generator>

The mist generator 90 shown in FIG. 1 includes a container 62 (62A), a gas supply unit 70 (70A), a discharge unit 74 (74A), an electrode 78 (78A), and a misting unit 80 in an external container 91. The container 62A includes a storage part 60A and a lid part 61A. The storage part 60A storages therein a liquid. The liquid is not particularly limited, and is preferably a dispersion liquid 63 including a dispersion medium 64 and particles 66.

The flow of mist generation with the use of the mist generator 90 will be described. First, the gas supply unit 70A supplies a gas to the storage part 60A. With a voltage applied to the electrode 78A from a power supply unit, not shown, and the gas described above is turned into plasma between the electrode 78A and the liquid level of the dispersion liquid 63 (hereinafter, which may be referred to simply as the “liquid level”). Next, the dispersion liquid 63 in the storage part 60A is turned into a mist by the misting unit 80. The misting unit 80 is, for example, an ultrasonic vibrator. The space between the container 62A and the external container 91 is filled with a liquid, and the vibration of the ultrasonic vibrator is transmitted through the liquid to the dispersion liquid 63 in the container 62A. As a result, the dispersion liquid 63 is turned into a mist. The dispersion liquid 63 may be turned into a mist while generating plasma, or after the plasma is generated. The dispersion liquid 63 may be turned into a mist after plasma irradiation for preventing aggregation of the particles 66, but is preferably turned into a mist during plasma irradiation for improving the dispersibility of the particles 66. Then, the dispersion liquid 63 turned into the mist (hereinafter, which may be simply referred to simply as the “mist”) is discharged from the discharge unit 74 to the outside, together with the gas fed from the gas supply unit 70.

The plasma in the present embodiment is an on-water plasma. The on-water plasma refers to plasma generated between: one or more electrodes disposed to face the liquid level of a liquid; and the liquid level of the liquid. In FIG. 1, the electrode 78 is provided to face the liquid level in the Z-axis direction. In addition, the number of electrodes is, for uniformly generating plasma in the storage part 60A, not limited to one, and two or more electrodes may be provided. The distance between the liquid level of the stationary liquid and the electrode 78 is preferably 30 mm or less, more preferably 5 nm to 10 mm.

In addition, a ground (G) electrode (not shown) may be provided under the container 62A for easily applying the generated plasma to the liquid level of the dispersion liquid.

When the plasma comes into contact with the dispersion liquid 63, OH radicals are generated. The OH radicals modify the surfaces of the particles to increase the repulsion between the particles, thereby allowing dispersibility of the particles to be improved.

For efficiently dispersing the particles 66 in the dispersion medium 64, a voltage may be applied at a frequency of 0.1 Hz or higher and 50 kHz or lower. The lower limit is preferably 1 Hz, more preferably 30 Hz. The upper limit is preferably 5 kHz, more preferably 1 kHz. In addition, the voltage applied to the electrodes is desirably 21 kV (electric field of 1.1×10⁶ V/m) or higher.

The material of the electrode 78A is not particularly limited, and copper, iron, titanium, or the like can be used.

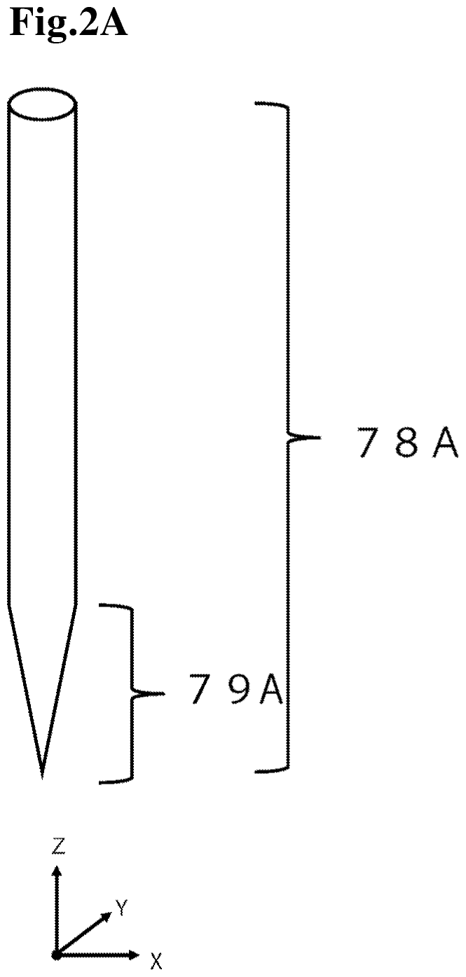

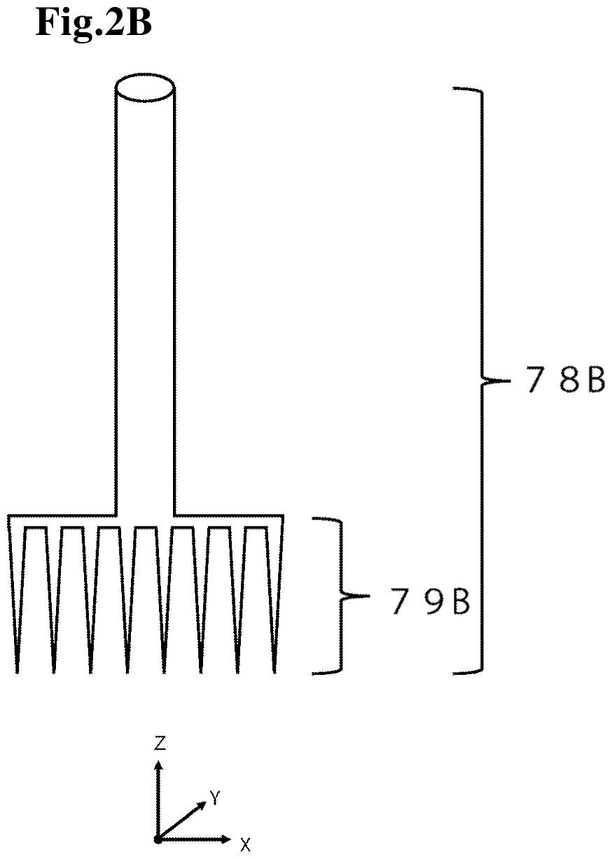

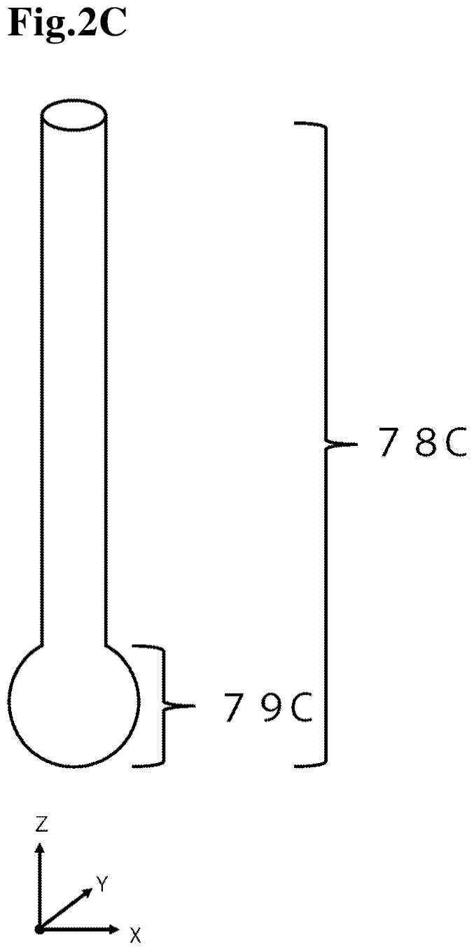

FIG. 2 is a schematic diagram illustrating an example of a tip 79 of the electrode 78 according to the first embodiment. FIG. 2A is an example of the electrode 78A with a tip 79A in a needle shape, FIG. 2B is an example of an electrode 78B with a plurality of needle-shaped parts for a tip 79B, and FIG. 2C is an example of an electrode 78C with a tip 79C in a spherical shape. It is to be noted that the electrodes 78B and 78C are modification examples of the electrode 78A. The electrode 78A has the tip 79A. When the tip 79A is viewed from the −Z-axis direction, a part of the tip 79A closest to the liquid level is preferably has an area reduced from the viewpoint of the plasma generation efficiency. Thus, the tip 79A has a needle shape (FIG. 2A). In addition, the shape of the tip of the electrode is not limited thereto. The electrode 78B has the tip 79B in a shape with a plurality of needle shapes (FIG. 2B). In addition, the electrode 78C has the spherical tip 79C (FIG. 2C). The dimensions and shape of the tip are not limited to those in these drawings.

In addition, the electrodes 78 shown in FIGS. 1 and 2 have a linear shape, but each may be bent.

In the mist generator 90 according to the present embodiment, the dispersion liquid 63 is preferably subjected to cooling. It is to be noted that the cooling herein also includes slow cooling. When the plasma is brought into contact with the dispersion liquid 63, the temperature of the dispersion liquid 63 may be increased. When the temperature of the dispersion liquid 63 is increased, the particles 66 are aggregated and settled in the dispersion liquid 63, and the dispersibility may be thus failed to be maintained. For example, the temperature increase of the dispersion liquid 63 can be suppressed by placing a cooling pipe (not shown) in the container 62A and circulating a refrigerant. In addition, for prevent impurities from being mixed into the dispersion liquid 63, a cooling pipe may be placed in the container 62A and the external container 91, and a refrigerant may be circulated through the cooling pipe (not shown) to adjust the temperature of the dispersion liquid. In addition, the temperature of the dispersion liquid 63 is preferably 40° C. or lower, more preferably 30° C. or lower. In addition, the temperature of the dispersion liquid 63 is preferably 0° C. or higher, and more preferably 10° C. or higher in order to easily fulfill the function of the ultrasound vibrator 80. The cooling may be performed during or after the generation of the plasma, but more preferably performed during the generation from the viewpoint of suppressing the temperature increase.

With reference to FIG. 1, an example in which the misting unit 80 is disposed away from the container 62A has been described, but the misting unit 80 may be in direct contact with the container 62A. In the case of preventing the heat generated in the misting unit 80 from thermally conducting directly to the container 62A, the misting unit 80 is preferably disposed away from the container 62A. In addition, in the case of disposing the misting unit 80 away from the container 62A, the space between the container 62A and the external container 91 is preferably filled with the liquid as described above. Such a configuration allows the vibration generated in the misting unit 80 to be propagated to the container 62A. In addition, the heat generated in the misting unit 80 by the vibration can also be cooled. It is to be noted that the liquid may be any liquid as long as the liquid can propagate the vibration, and water is preferred.

The mist obtained by the device according to the present embodiment can be suitably used for a film forming device, a film forming method, and the like described later.

The lid part 61A is a lid for the storage part 60A. The lid part 61A may be provided, or no lid part 61A may be provided. In the mist generator 90 shown in FIG. 1, the gas supply unit 70A, the discharge unit 74A, and the electrode 78A are inserted through the lid part 61A. The lid part 61A may have such a structure for sealing the container 62A, or may have a structure without sealing. It is to be noted that if the lid part 61A has a structure for sealing the container 62A, the container 62A is easily filled with a gas, and the plasma generation efficiency can be thus made favorable.

The storage part 60A is a container that stores the dispersion liquid 63. The material of the container is not particularly limited, but the material may be a plastic or a metal for efficiently propagating the vibration generated in the misting unit 80 to the dispersion liquid 63.

The particles 66 are preferably inorganic oxides. The inorganic oxides are not particularly limited, but are preferably silicon dioxides, zirconium oxides, indium oxides, zinc oxides, tin oxides, titanium oxides, indium tin oxides, potassium tantalates, tantalum oxides, aluminum oxides, magnesium oxides, hafnium oxides, tungsten oxides, or the like. These fine particles may be used singly, or two or more thereof may be combined arbitrarily.

The average particle size of the particles 66 is not particularly limited, but can be 5 nm to 1000 nm. It is to be noted that the lower limit is preferably 10 nm, more preferably 15 nm, still more preferably 20 nm, even still more preferably 25 nm. The upper limit is preferably 800 nm, more preferably 100 nm, still more preferably 50 nm. The average particle size in this specification is a median diameter from the scattering intensity obtained by dynamic light-scattering spectroscopy.

The type of the dispersion medium 64 is not particularly limited, as long as the particles can be dispersed. As the dispersion medium, water, alcohols such as an isopropyl alcohol (IPA), an ethanol, and a methanol, an acetone, a dimethylformamide (DMF), a dimethylsulfoxide (DMSO), an ethyl acetate, an acetic acid, a tetrahydrofuran (THF), a diethyl ether (DME), a toluene, a carbon tetrachloride, an n-hexane, and the like, and mixtures thereof can be used, for example. Among these media, from viewpoints such as the dispersibility and dielectric constant of the particles, the dispersion medium preferably contains water as a dispersion medium, and is more preferably a water solvent.

The concentration of the particles 66 in the dispersion liquid 63 is not particularly limited, but can be set to be 0.001% by mass to 80% by mass from viewpoints such as the resulting dispersion effect. Further, the upper limit is preferably 50% by mass, more preferably 25% by mass, still more preferably 10% by mass. The lower limit is preferably 1% by mass, more preferably 2% by mass, still more preferably 3% by mass.

The type of the gas as a plasma source for generating the plasma is not particularly limited, and known gases can be used. Specific examples of the gas include helium, argon, xenon, oxygen, nitrogen, and air. Among these examples, helium, argon, and xenon with high stability are preferred.

The plasma generation time is not particularly limited, but the total generation time can be 25 seconds to 1800 seconds or less from the viewpoint of favorably dispersing the particles 66. It is to be noted that the lower limit is preferably 25 seconds. In addition, the upper limit is preferably 1800 seconds, more preferably 900 seconds, still more preferably 600 seconds. In addition, the plasma may be generated continuously (once) or intermittently. Even in the case of intermittent generation, the total generation time is desirably the irradiation time described above.

The gas supply unit 70A introduces a gas fed from the outside of the mist generator 90 into the container 62A. The shape of the gas supply unit 70A is not limited to a cylindrical shape. The gas supply opening 72A of the gas supply unit 70A is placed in the storage part 60A. The shape of the gas supply opening 72A is not limited to a circular shape.

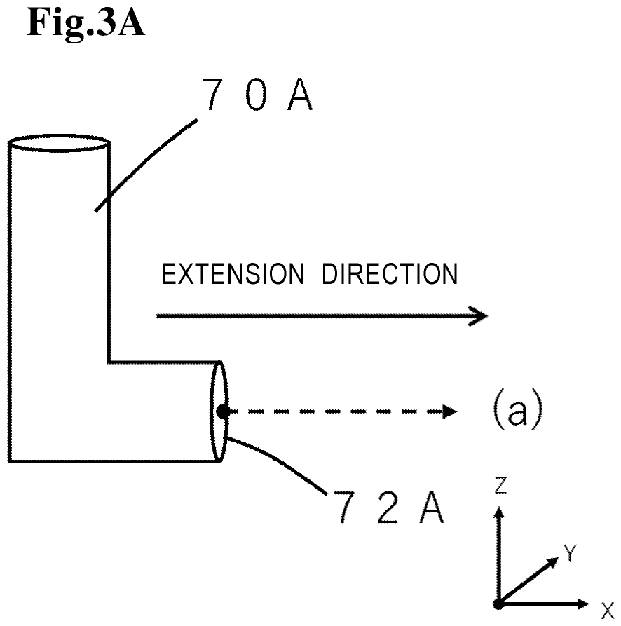

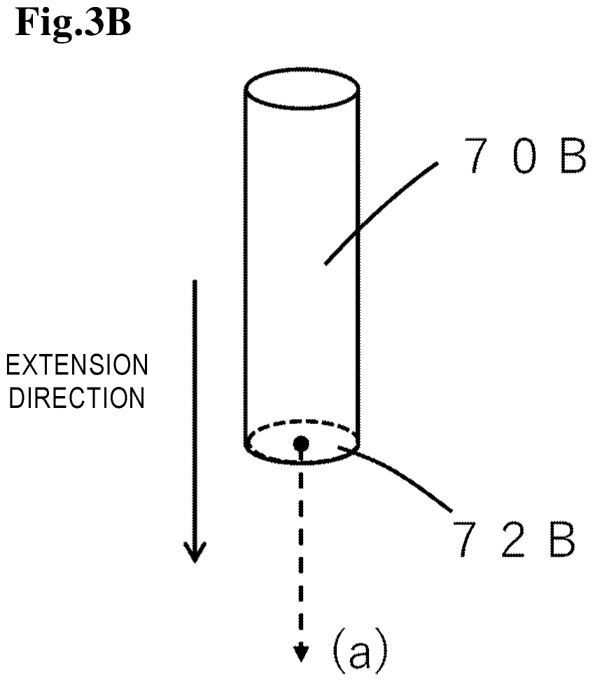

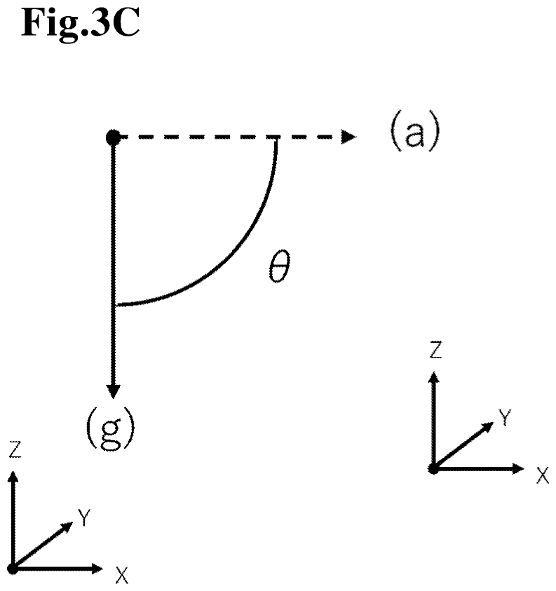

FIG. 3 is a schematic diagram showing an example of a supply direction and the angle θ made by the supply direction and the direction of gravitational force. FIG. 3A is a schematic diagram showing an example of the gas supply unit 70A according to the first embodiment and illustrating the supply direction. FIG. 3B is a schematic diagram illustrating the supply direction of a gas supply unit 70B. FIG. 3C is a diagram for illustrating the angle θ in FIG. 3A.

The supply directions of the gases supplied from the gas supply opening 72A and the gas supply opening 72B in the gas supply unit 70A and the gas supply unit 70B will be described with reference to FIGS. 3A and 3B. The supply direction refers to a direction (extension direction) in which the gas supply unit 70 is extended from the gas supply opening 72. In the case of FIG. 3A, the extension direction of the gas supply unit 70A is the +X-axis direction, and the supply direction is the +X-axis direction as indicated by an arrow (a). In the case of FIG. 3B, the extension direction of the gas supply unit 70B is the direction of gravitational force, and the supply direction is the direction of gravitational force (−Z-axis direction) as indicated by an arrow (a). It is to be noted that the arrow (a) is a line drawn in the supply direction from the center of gravity of the gas supply opening 72.

Next, the angle θ made by the supply direction and the direction of gravitational force (g) will be described with reference to FIG. 3C (in FIG. 3C, the gas supply unit of FIG. 3A is used). Of the angles made by the supply direction and the direction of gravitational force, the smaller angle is referred to as the angle θ made by the supply direction and the direction of gravitational force. For example, in the case of the present embodiment, θ is 90 degrees.

In the case of the mist generator shown in FIG. 1, the part where the arrow (a) (the line drawn in the supply direction from the center of gravity of the gas supply opening 72) intersects first is the side surface of the container 62A, and the momentum of the fed gas is weakened. More specifically, the mist generator is configured such that the part where the line drawn in the supply direction from the center of gravity of the gas supply opening 72 intersects first is not the liquid level of the dispersion liquid 63. Thus, it is possible to stably generate plasma without significantly undulating the liquid level. When the gas directly hits the liquid level, the liquid level is significantly undulated. As a result, the electrode 78A comes into contact with the liquid level of the dispersion liquid 63, and no plasma is generated between the electrode 78A and the dispersion liquid 63.

According to the present embodiment, the gas supply opening 72 and the liquid level of the dispersion liquid 63 preferably do not face each other. In this regard, the phrase “the gas supply opening and the liquid level of the dispersion liquid do not face each other” in this specification means that the part where the line in the supply direction drawn from the center of gravity of the gas supply opening 72 intersects first is a part other than the liquid level of the dispersion liquid.

The discharge unit 74A discharges the mist and gas generated in the storage part 60A to the outside of the container 62A. The shape of the discharge unit 74A unit is not limited to a cylindrical shape. The discharge opening 76A of the discharge unit is placed in the storage part 60A to discharge the mist and the gas from the inside of the storage part 60A to the outside of the mist generator 90. The shape of the discharge opening 76A is not limited to a circular shape.

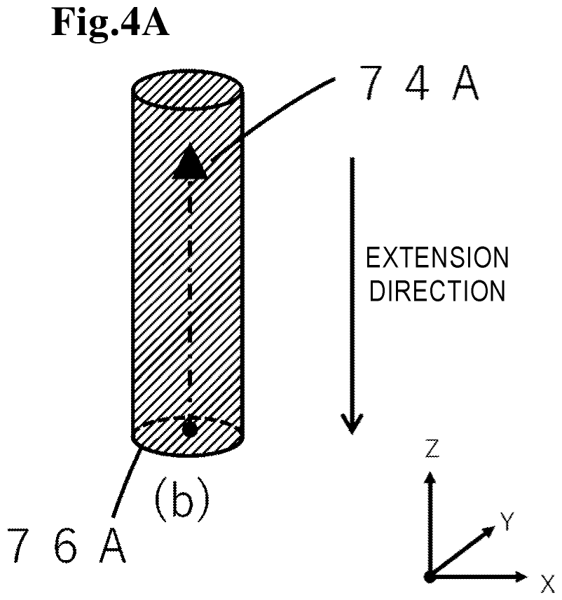

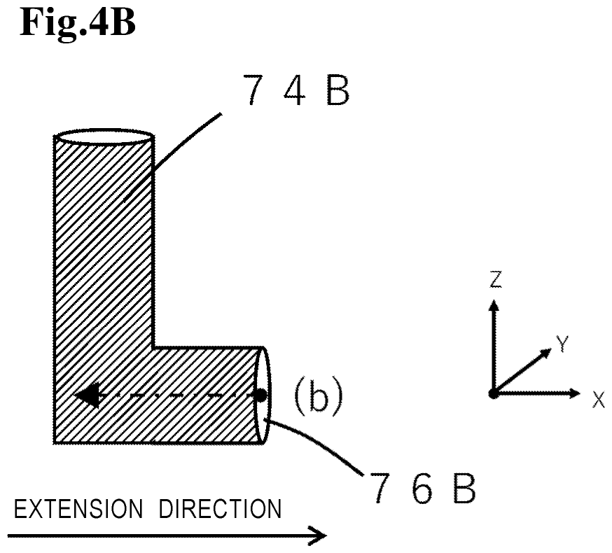

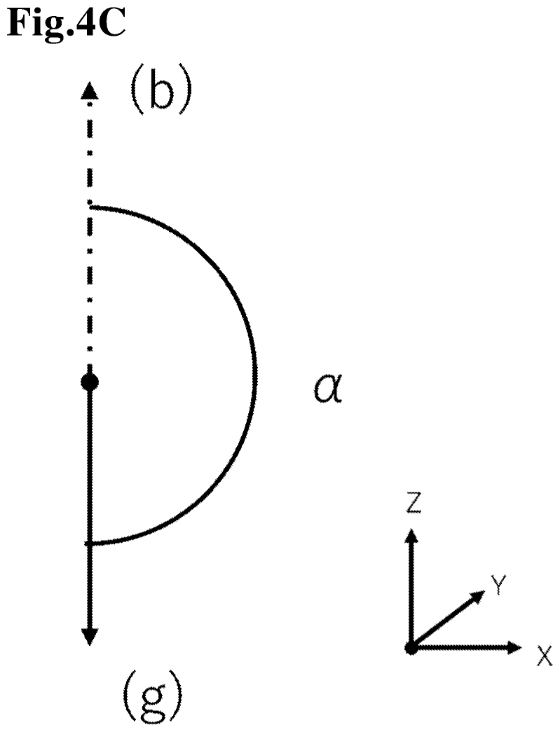

FIG. 4 is a schematic diagram showing an example of a discharge direction and the angle α made by the discharge direction and the direction of gravitational force. FIG. 4A is a schematic diagram showing an example of a discharge unit 74A according to the first embodiment and illustrating the discharge direction. FIG. 4B is a schematic diagram illustrating the discharge direction of a discharge unit 74B. FIG. 4C is a diagram for illustrating the angle α in FIG. 4A.

The discharge directions of the mists and gases discharged from the discharge opening 76A and the discharge opening 76B in the discharge unit 74A and the discharge unit 74B will be described with reference to FIGS. 4A and 4B. In addition, the discharge direction refers to a direction opposite to a direction (extension direction) in which the discharge unit 74 is extended from the discharge opening 76. In the case of FIG. 4A, the opposite direction of the extension direction of the discharge unit 74A is the +Z-axis direction, and the discharge direction is the +Z-axis direction as indicated by an arrow (b). In the case of FIG. 4B, the opposite direction of the extension direction of the discharge unit 74B is the −X-axis direction, and the discharge direction is the −X-axis direction. In this regard, the arrow (b) is considered drawn in the discharge direction from the center of gravity of the discharge opening 76.

Next, the angle α made by the discharge direction and the direction of gravitational force (g) will be described with reference to FIG. 4C (in FIG. 4C, the discharge unit of FIG. 4A is used). As shown in FIG. 4C, of the angles made by the discharge direction and the direction of gravitational force, the smaller angle is referred to as the angle α made by the discharge direction and the direction of gravitational force. It is to be noted that, as in the present embodiment, when the two directions are opposite to each other, there are two angles of 180 degrees, and in this case, one of the angles is regarded as a. In FIG. 4C, the counterclockwise angle as viewed from the direction of gravitational force is used to define 180 degrees, but the clockwise angle may be used to define 180 degrees.

In the case of α=180 degrees, the liquid level and the discharge opening 76A face each other, and the generated mist is thus efficiently discharged to the outside of the container 62A.

The gas supply opening 72A may be placed above or below the discharge opening 76A. For more easily stirring the fed gas and discharging the uniform mist to the outside of the container 62A, however, the gas supply opening 72A is preferably placed below the discharge opening 76A.

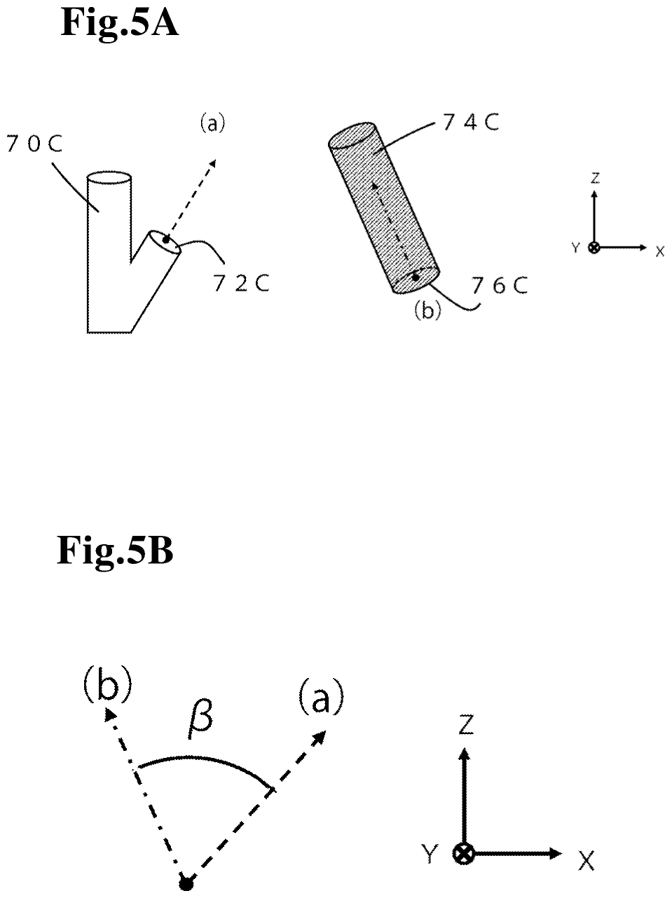

FIG. 5 is an explanatory diagram showing an example of the angle β made by a supply direction and a discharge direction. FIG. 5A is a schematic diagram of a gas supply unit 70C and a discharge unit 74C according to the first embodiment. FIG. 5B is a diagram for illustrating the angle β. The supply direction (represented by an arrow (a) herein) and discharge direction (represented by an arrow (b) herein) shown in FIG. 5A are illustrated in FIG. 5B. In FIG. 5B, of the angles made by the two directions, the smaller angle is referred to as the angle β made by the supply direction and the discharge direction. The angle β made is desirably an angle such that the gas discharged from the discharge unit 74C contains therein a mist. Thus, the angle β made may be 30 degrees to 150 degrees. The upper limit may be 135 degrees or 120 degrees. The lower limit may be 60 degrees, and is more preferably 90 degrees.

It is to be noted that although FIGS. 3A and 4A show a case of θ=90 degrees and α=180 degrees, the present embodiment is not limited thereto. Modification examples will be described below.

### First Embodiment: Modification Example 1

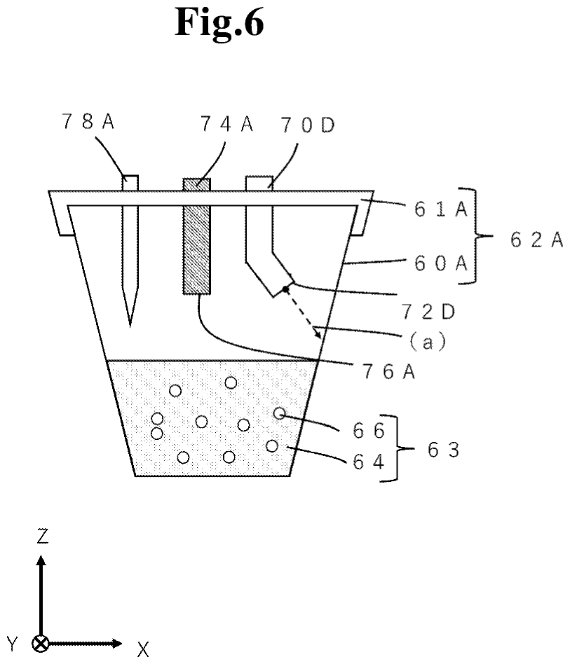

FIG. 6 is a schematic diagram showing an example of a mist generator 90 according to Modification Example 1 of the first embodiment. Hereinafter, differences from the embodiments described above will be described. It is to be noted that the mist generators 90 according to the embodiment and modification examples thereof, shown in FIGS. 6 to 18 each include an external container 91 and a misting unit 80, which are similar to those of the embodiment described above. Accordingly, in the examples shown below, the illustration of the misting unit 80 and external container 91 is omitted.

The mist generator 90 shown in FIG. 6 has a gas supply unit 70D. The gas supply unit 70D has a gas supply opening 72D, with θ<90 degrees. In the present modification example, the part where the arrow (a) (the line drawn in the supply direction from the center of gravity of the gas supply opening 72D) intersects first is the side surface of a storage part 60A. When the gas collides with the side surface of the container, the momentum of the fed gas is weakened, thereby allowing the gas to be fed into a container 62A without disturbing the liquid level. In the present modification example, the part where the arrow (a) intersects first is not limited to the side surface of the storage part 60A, and may be a discharge unit 74A or an electrode 78A.

### First Embodiment: Modification Example 2

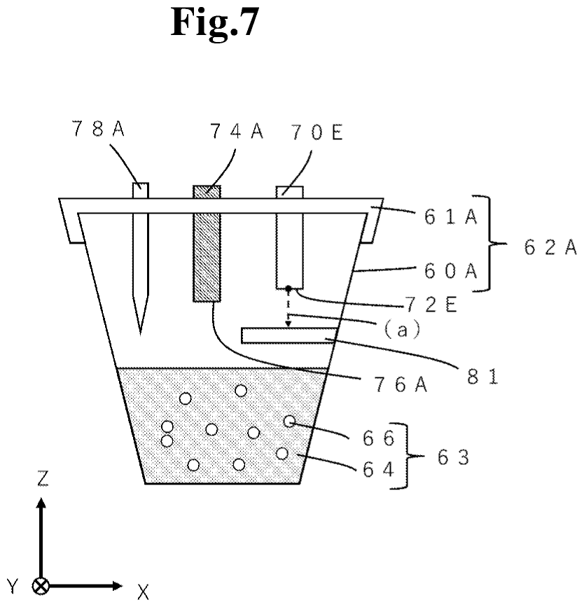

FIG. 7 is a schematic diagram showing an example of a mist generator 90 according to Modification Example 2 of the first embodiment. The mist generator 90 shown in FIG. 7 has a plate-shaped member 81 placed below a gas supply unit 70E (θ=0 degrees). More specifically, the plate-shaped member 81 is disposed between the gas supply unit 70E and the liquid level of a dispersion liquid 63. The part where the arrow (a) (the line drawn in the supply direction from the center of gravity of the gas supply opening 72E) intersects first is the plate-shaped member 81, thus weakening the momentum of the fed gas, and allowing the gas to be fed into the container 62A without disturbing the liquid level. In addition, the angle of θ is not limited to 0 degrees, as long as the part with which the arrow (a) first comes into contact may be a plate-shaped member.

### First Embodiment: Modification Example 3

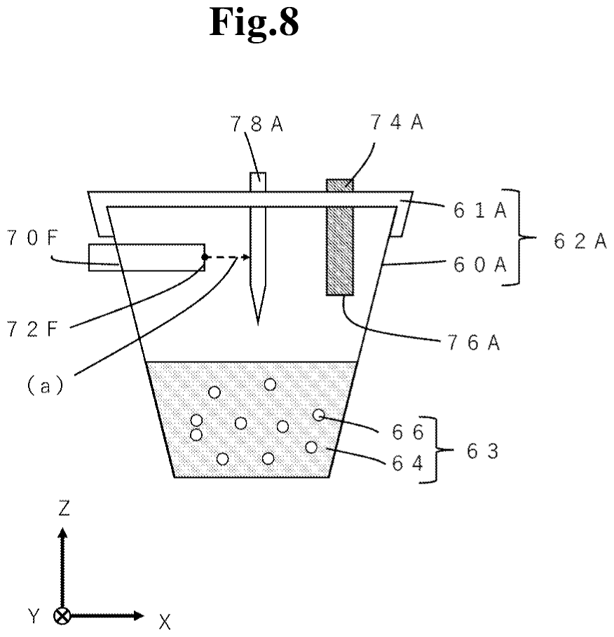

FIG. 8 is a schematic diagram showing an example of a mist generator 90 according to Modification Example 3 of the first embodiment. The mist generator 90 shown in FIG. 8 has a gas supply unit 70F inserted from the side surface of a storage part 60A. In the present modification example, the part where the arrow (a) (the line drawn in the supply direction from the center of gravity of a gas supply opening 72F) intersects first is the side surface of an electrode 78A. The part where the arrow (a) intersects first is not limited to the electrode 78A, and may be the discharge unit 74A, the side surface of the storage part 60A or a lid part 61A.

### First Embodiment: Modification Example 4

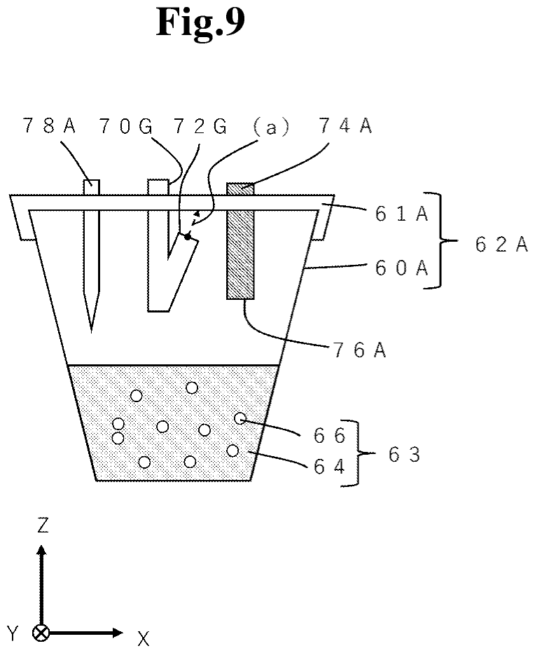

FIG. 9 is a schematic diagram showing an example of a mist generator 90 according to Modification Example 4 of the first embodiment. The mist generator 90 shown in FIG. 9 includes a gas supply unit 70G where the angle θ made by the supply direction and the direction of gravitational force is made larger than 90 degrees while the angle α made by the discharge direction and the direction of gravitational force is kept at 180 degrees. The part where the arrow (a) (the line drawn in the supply direction from the center of gravity of a gas supply opening 72G) intersects first desirably does not intersect the liquid level, and the gas fed from the gas supply opening 72G is not directly blown to the liquid level, thus preventing the liquid level to be prevented from significantly waving. The angle θ made may be 90 degrees to 150 degrees. The upper limit may be 135 degrees or 120 degrees. The lower limit may be 100 degrees or 105 degrees.

### First Embodiment: Modification Example 5

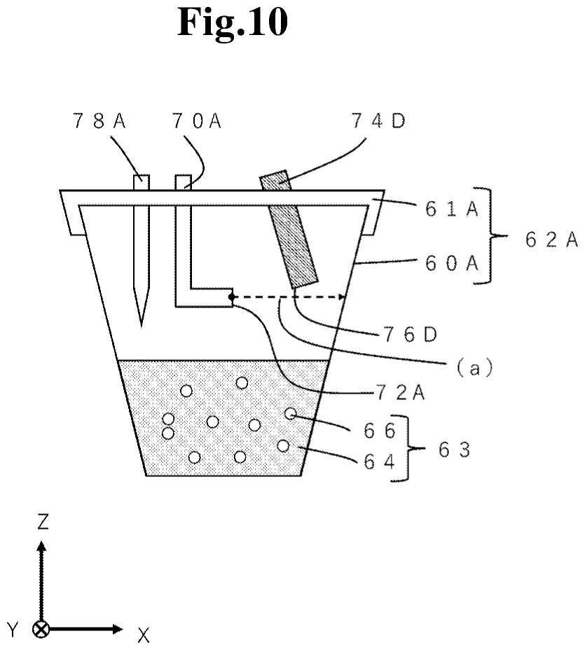

FIG. 10 is a schematic diagram showing an example of a mist generator 90 according to Modification Example 5 of the first embodiment. The mist generator 90 shown in FIG. 10 includes a discharge unit 74D where the angle α made by the discharge direction and the direction of gravitational force is made smaller than 180 degrees while the angle θ made by the supply direction and the direction of gravitational force is kept at 90 degrees. The angle α made may be 120 degrees to 180 degrees for efficiently collecting the generated mist. The upper limit may be 165 degrees or 150 degrees. The lower limit may be 130 degrees or 135 degrees.

### Second Embodiment

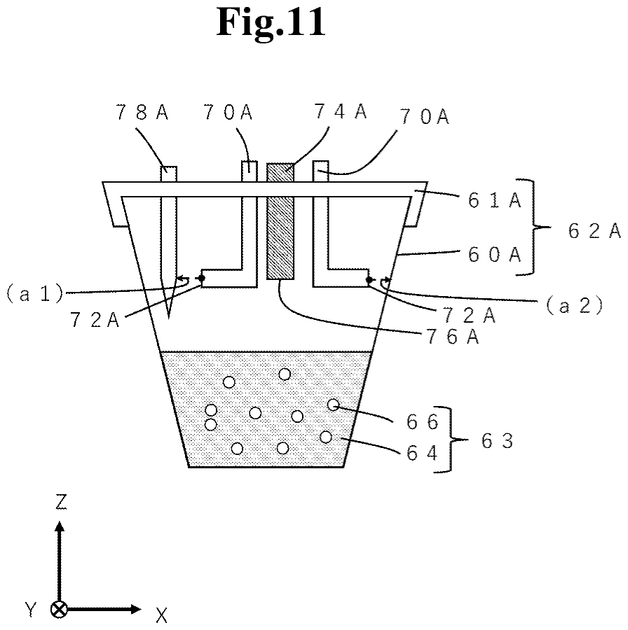

A second embodiment will be described with reference to FIG. 11. Hereinafter, differences from the embodiments described above will be described. Each configuration according to the second embodiment is considered the same as that according to the first embodiment, unless otherwise described.

FIG. 11 is a schematic diagram showing an example of a mist generator 90 according to the second embodiment. The mist generator 90 according to the present embodiment includes two or more gas supply units 70A. FIG. 11 shows the layout configuration of a container 62A, the two gas supply units 70A, a discharge unit 74A, and an electrode 78A in the mist generator 90 according to the second embodiment. It is to be noted that the illustration of the misting unit 80 is omitted in FIG. 11.

The mist generator 90 shown in FIG. 11 has a configuration including the two gas supply units 70A. When the number of gas supply units 70A is increased, a large amount of gas can be fed into the container 62A at a time. When a large amount of gas is to be fed into the container 62A by one gas supply unit 70A, the gas with a high flow rate will be locally fed even if the gas is not directly fed to the liquid level of a dispersion liquid 63, and the air flow in the container 62A may be thus significantly disturbed, thereby significantly undulating the liquid level. The increased number of gas supply units 70A makes it possible to suppress an increase in the flow rate of the gas fed from one gas supply unit 70A while increasing the amount of the gas fed, thus, making it possible to keep the liquid level of the dispersion liquid 63 from significantly undulating.

It is to be noted that the number of gas supply units 70A is not limited to two, and may be three or more. In addition, although the configuration shown in FIG. 11 has been described in the present embodiment, the present invention is not limited thereto, and the gas supply units 70A to 70G described in the first embodiment may be used in combination.

### Third Embodiment

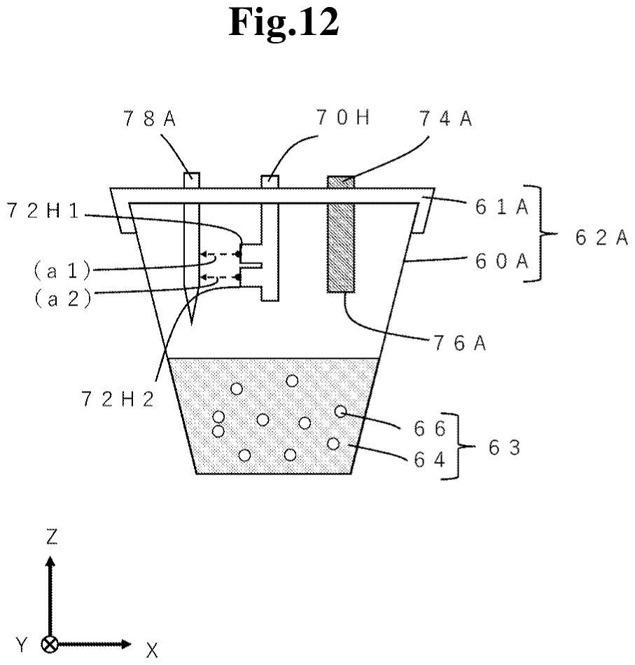

A third embodiment will be described with reference to FIG. 12. Each configuration according to the third embodiment is considered the same as that according to the first embodiment, unless otherwise described.

FIG. 12 is a schematic diagram showing an example of a mist generator 90 according to the third embodiment. The mist generator 90 according to the present embodiment has two or more gas supply openings 72H. FIG. 12 shows the layout configuration of a container 62A, a gas supply unit 70H, a discharge unit 74A, and an electrode 78A in the mist generator 90 according to the third embodiment. It is to be noted that the illustration of the misting unit 80 is omitted in FIG. 12.

The mist generator 90 shown in FIG. 12 has a configuration including one gas supply unit 70H with two gas supply openings 72H1 and H2. When a large amount of gas is to be fed into the container 62A through one gas supply opening 72H1 (H2), the flow rate per unit time per gas supply opening 72H1 (H2) will be increased. Thus, the gas with a high flow rate will be locally fed in the container 62A even if the gas is not directly fed to the liquid level, and the air flow in the container 62A may be thus significantly disturbed, thereby significantly undulating the liquid level of a dispersion liquid 63.

Providing the plurality of gas supply openings 72H1 (H2) for one gas supply unit 70H reduces the flow rate per unit time per gas supply opening 72H1 (H2). As a result, even when a large amount of gas is fed into the container 62A, the liquid level of the dispersion liquid 63 can be kept from significantly undulating.

The number of the gas supply openings 72H1 (H2) is not limited to two, and may be three or more. It is to be noted that the present embodiment is not limited thereto, and the gas supply opening 72 described in the first embodiment described above may be combined.

### Third Embodiment: Modification Example

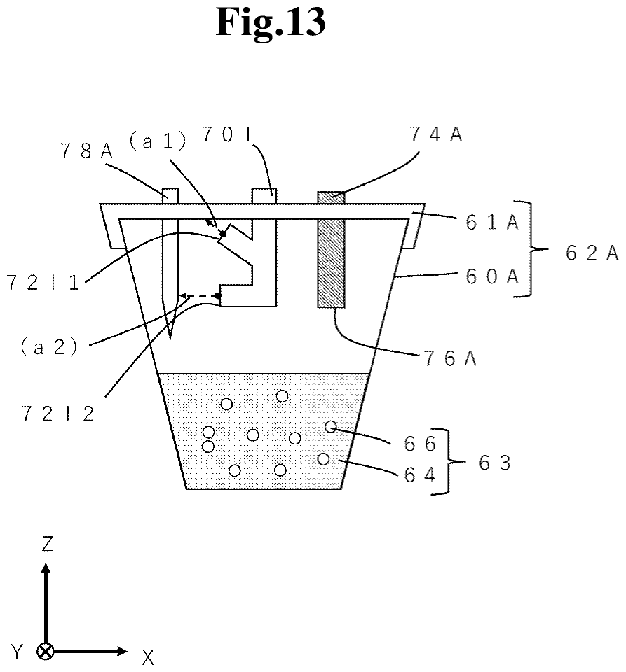

FIG. 13 is a schematic diagram showing a modification example of the mist generator 90 according to the third embodiment. The gas supply unit 70I shown in FIG. 13 has two gas supply openings 72I1 and I2 that differ in inclination. It is to be noted that the gas supply unit 70I according to the present modification example has only to have a plurality of gas supply openings 72I that differ in inclination, and the plurality of gas supply openings 72I has only to satisfy the above-described angle θ and angle β made with respect to each supply direction. In addition, a plurality of gas supply units 70 may be further combined as described in the second embodiment.

### Fourth Embodiment

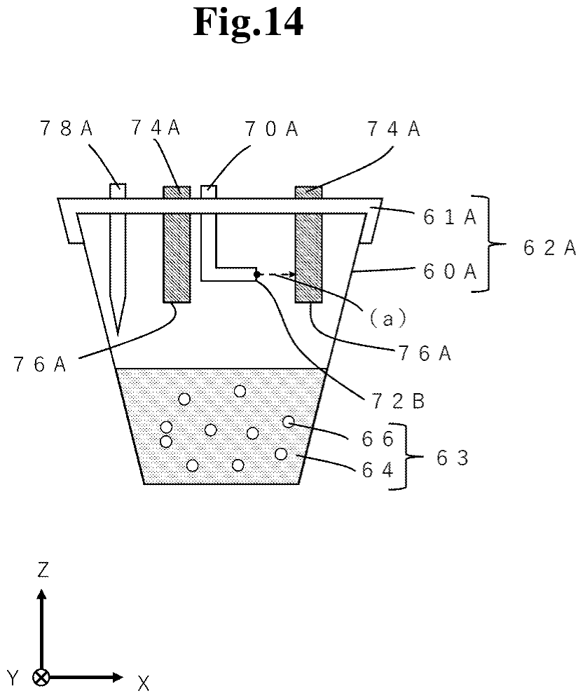

A fourth embodiment will be described with reference to FIG. 14. Each configuration according to the fourth embodiment is considered the same as that according to the first embodiment, unless otherwise described. The mist generator 90 according to the present embodiment has two or more discharge units 74A.

FIG. 14 is a schematic diagram showing an example of the mist generator according 90 to the fourth embodiment. FIG. 14 shows the layout configuration of a container 62A, a gas supply unit 70A, the two discharge units 74A, and an electrode 78A in the mist generator 90 according to the fourth embodiment. It is to be noted that the illustration of the misting unit 80 is omitted in FIG. 14.

The mist generator 90 shown in FIG. 14 has a configuration including the two discharge units 74A. When the number of discharge units 74A is increased, a large amount of gas can be discharged from the inside of the container 62A at a time. In addition, the mist generated in the container 62A can be discharged evenly.

It is to be noted that the number of discharge units 74A is not limited to two, and may be three or more. Although the configuration shown in FIG. 14 has been described in the present embodiment, the present invention is not limited thereto, and two or more discharge units 74 may be provided in the first to third embodiments described above.

### Fifth Embodiment

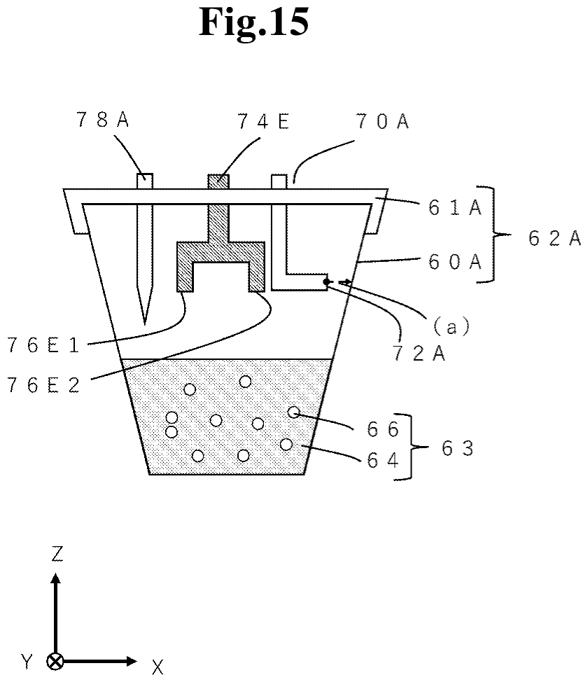

A fifth embodiment will be described with reference to FIG. 15. Each configuration according to the fifth embodiment is considered the same as that according to the first embodiment, unless otherwise described.

FIG. 15 is a schematic diagram showing an example of a mist generator 90 according to a fifth embodiment. The mist generator 90 according to the present embodiment has two or more discharge openings 76E. FIG. 15 shows the layout configuration of a container 62A, a gas supply unit 70A, a discharge unit 74E, and an electrode 78A in the mist generator 90 according to the fifth embodiment. It is to be noted that the illustration of the misting unit 80 is omitted in FIG. 15.

The mist generator 90 shown in FIG. 15 has a configuration including two discharge openings 76E1 and E2 for one discharge unit 74E. When large amounts of gas and mist are to be discharged from the inside of the container 62A by one discharge unit 74E, the flow rate per unit time per discharge opening 76E1 (E2) will be increased. Thus, the liquid level may significantly undulate. Providing the plurality of discharge openings 76E1 (E2) for one discharge unit 74E reduces the flow rate per unit time per discharge opening 76E1 (E2). As a result, the liquid level can be kept from greatly undulating. In addition, the discharge openings 76E1 (E2) are resent at different positions, thus allowing the mist generated in the container 62A to be uniformly and evenly discharged.

The number of discharge openings 76E1 (E2) is not limited to two, and may be three or more. It is to be noted that the configuration of the discharge unit 74E is not limited to the configuration shown in FIG. 15.

### Fifth Embodiment: Modification Example

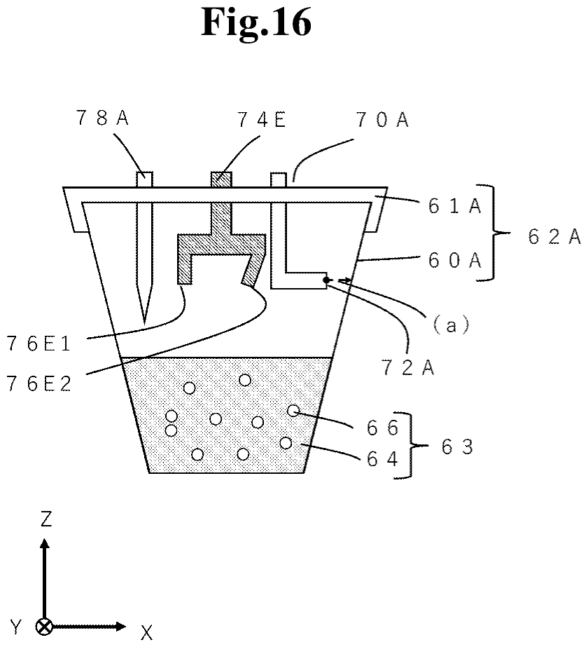

FIG. 16 is a schematic diagram showing a modification example of the mist generator 90 according to the fifth embodiment. The discharge unit 74E shown in FIG. 16 has two discharge openings 76E1 and E2 that differ in inclination. It is to be noted that the discharge unit 74E according to the present modification example has only to have a plurality of discharge openings 76E that differ in inclination, and as described in the first embodiment, each discharge opening 76E has only to satisfy the above-described angle α and angle β with respect to each discharge direction. In addition, as described in the fourth embodiment, the mist generator 90 may have a plurality of discharge units 74 used in combination.

### Sixth Embodiment

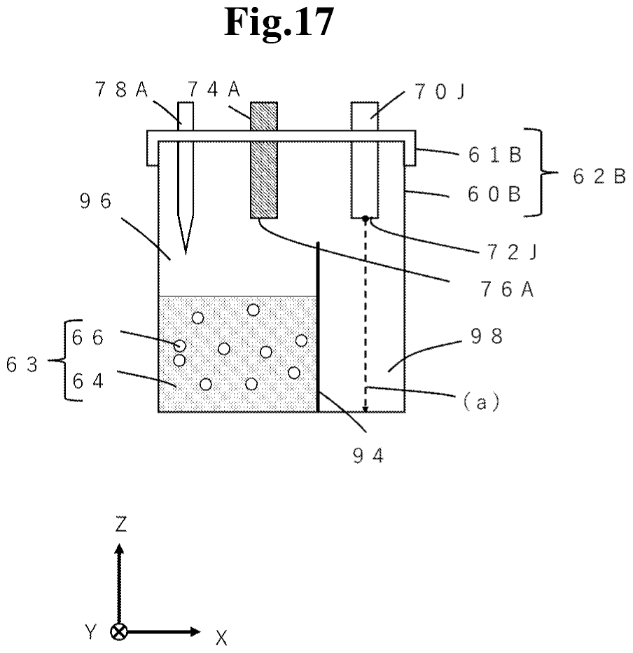

A sixth embodiment will be described with reference to FIG. 17. Each configuration according to the sixth embodiment is considered the same as that according to the first embodiment, unless otherwise described.

FIG. 17 is a schematic diagram showing an example of a mist generator 90 according to the sixth embodiment. FIG. 17 shows the layout configuration of a container 62B, a gas supply unit 70J, a discharge unit 74A, and an electrode 78A in the mist generator 90 according to the sixth embodiment. It is to be noted that the illustration of the misting unit 80 is omitted in FIG. 17.

The container 62B shown in FIG. 17 has a partition 94 provided in a storage part 60B. The storage part 60B has therein two spaces. The space in which a dispersion liquid is stored is a storage space 96. The space in which no dispersion liquid 63 is stored is an empty space 98. The numbers of storage spaces 96 and empty spaces 98 are not limited to one, and may be more than one. The empty space 98 has a gas supply opening 72J placed therein.

Further, for discharging, from the discharge unit 74A, the gas fed from the gas supply opening 72J into the container 62B, the partition 94 does not have a height that reaches a lid part 61B for the container 62B, and the storage space 96 and the empty space 98 are opened in an upper section of the storage part 60B. In other words, the space partitioned by the partition 94 with the dispersion liquid 63 stored therein and expanding in the upward direction until reaching the lid part 61B is defined as the storage space 96, and the space partitioned by the partition 94 without any dispersion liquid stored therein and expanding in the upward direction until reaching the lid part 61B is defined as the empty space 98.

Providing the gas supply opening 72J in the empty space 98 allows the container 62B to be filled with a gas without blowing the gas directly onto the dispersion liquid 63. In addition, the discharge unit 74A is located in the storage space 96. As a result, a mist can be efficiently discharged to the outside of the container 62B. It is to be noted that the present embodiment is not limited to the example shown in the drawing.

### Sixth Embodiment: Modification Example

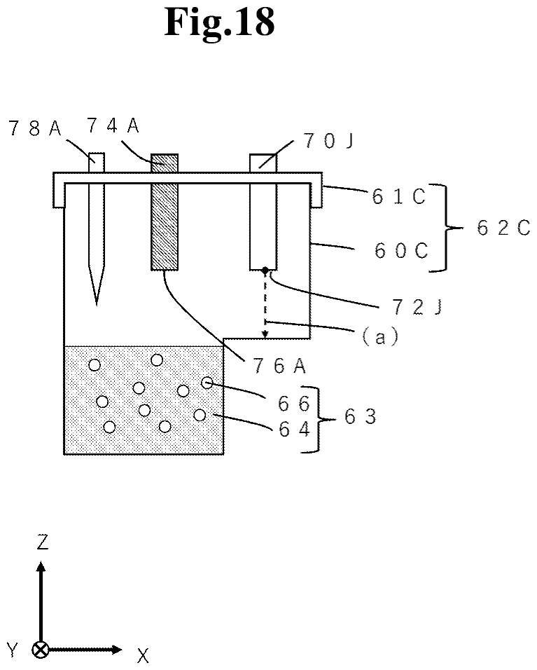

FIG. 18 is a schematic diagram showing a modification example of the mist generator 90 according to the sixth embodiment. The container 62C shown in FIG. 18 has a step. The dispersion liquid 63 is stored up to the height of the step. The number of steps is not limited to one, and may be more than one.

The gas supply opening 72J is placed at a position that does not face the liquid level. Thus, the container 62C can be filled with the gas without supplying the gas directly to the liquid level. A discharge opening 76A is placed at a position that faces the liquid level, thereby allowing a generated mist to be efficiently discharged to the outside of the container 62C. The present embodiment is not limited thereto, and the gas supply unit 70 and the discharge unit 74 according to the first to fifth embodiments described above may be used in combination.

### Seventh Embodiment

<Thin Film Manufacturing Device/Manufacturing Method>

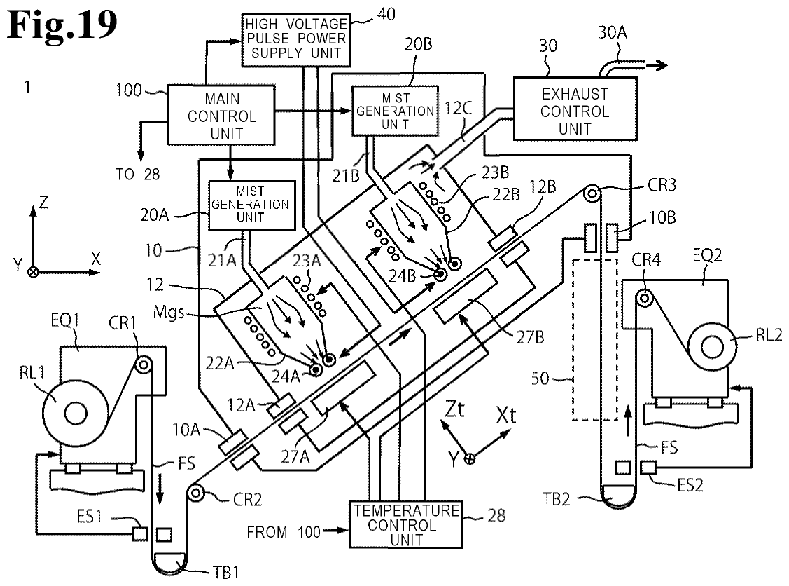

The mist generator 90 according to the aspect of the present invention allows a thin film to be formed by, for example, the following device. Hereinafter, a description will be given with reference to FIG. 19.

FIG. 19 is a diagram illustrating a configuration example of a thin film manufacturing device 1 according to the seventh embodiment, which is one of the configurations of a manufacturing device of electronic devices. A mist generation unit 20A and a mist generation unit 20B according to the present embodiment correspond to the mist generator 90 described above. In addition, a duct 21A and a duct 21B correspond to the discharge unit 74 described above.

The thin film manufacturing device 1 according to the present embodiment continuously forms a thin film of the particles 66 on the surface of a flexible long sheet substrate FS by a roll-to-roll (Roll to Roll) method.

[Schematic Configuration of Device]

In FIG. 19, an XYZ orthogonal coordinate system is defined so that the floor surface of a factory where the device main body is installed is regarded as an XY plane, whereas the direction perpendicular to the floor surface is regarded as a Z-axis direction. In addition, in the thin film manufacturing device 1 of FIG. 19, the surface of the sheet substrate FS always perpendicular to the XZ plane is supposed to be conveyed in the longitudinal direction.

The long sheet substrate FS (hereinafter, referred to simply as a substrate FS) as an object to be processed is wound around a supply roll RL1 attached to a mount EQ1 over a predetermined length. The mount EQ1 is provided with a roller CR1 for hanging the sheet substrate FS drawn out from the supply roll RL1, and the rotation center axis of the supply roll RL1 and the rotation center axis of the roller CR1 extend in the Y-axis direction (the direction perpendicular to the paper surface of FIG. 19) so as to be parallel to each other. The substrate FS bent in the −Z-axis direction (gravitational direction) by the roller CR1 is folded back in the Z-axis direction by an air turn bar TB1, and is bent obliquely upward (in the range of 450° 15° with respect to the XY plane) by a roller CR2. The air turn bar TB1 is, for example, as described in WO2013/105317, intended to turn the conveying direction, with direction the substrate FS slightly floated by an air bearing (gas layer). It is to be noted that the air turn bar TB1 is movable in the Z-axis direction by driving a pressure regulation unit, not shown, and applies tension to the substrate FS in a non-contact manner.

The substrate FS passing through the roller CR2 is passed through a slit-like air-sealing part 10A of a first chamber 10, and then passed through a slit-like air-sealing part 12A of a second chamber 12 that houses a film formation main body, and carried linearly in an obliquely upward direction into the second chamber 12 (film formation main body). When the substrate FS is fed at a constant speed in the second chamber 12, a film of the particle 66 with a predetermined thickness is formed on the surface of the substrate FS by a mist deposition method assisted by atmospheric pressure plasma or a mist CVD (Chemical Vapor Deposition) method.

The substrate FS subjected to film formation processing in the second chamber 12 is discharged from the second chamber through a slit-like air-sealing part 12B, bent in the −Z-axis direction by a roller CR3, and then bent by a roller CR4 provided on a mount EQ2 and wound up by a collection roll RL2. The collection roll RL2 and the roller CR4 are provided on the mount EQ2 to extend in the Y-axis direction (the direction perpendicular to the paper surface of FIG. 19) such that their rotation center axes are parallel to each other. Further, if necessary, a drying unit (heating unit) 50 for drying unnecessary water components attached to the substrate FS or with which the substrate FS impregnated may be provided in the conveying path from the air-sealing part 10B to the air turn bar TB2.

The air-sealing parts 10A, 10B, 12A, and 12B shown in FIG. 19 are, as disclosed in WO2012/115143, provided with slit-like apertures that carries in and out the sheet substrate FS in the longitudinal direction, while blocking the flow of gas (atmospheric air, etc.) between spaces inside and outside the outer wall of the first chamber 10 or the second chamber 12. Air bearings (static pressure gas layers) of vacuum pressurized method are formed between the upper edge sides of the apertures and the upper surface (surface to be processed) of the sheet substrate FS, and between the lower edge sides of the apertures and the lower surface (back surface) of the sheet substrate FS. Therefore, the mist gas for film formation remains in the second chamber 12 and in the first chamber 10, such that the gas is prevented from leaking to the outside.

In the case of the present embodiment herein, the conveyance control and the tension control in the longitudinal direction of the substrate FS are achieved by a servomotor provided on the mount EQ2 so as to rotationally drive the collection roll RL2, and a servomotor provided on the mount EQ1 so as to rotationally drive the supply roll RL1. Although not shown in FIG. 19, the respective servomotors provided on the mount EQ2 and the mount EQ2 are controlled by a motor control unit, such that predetermined tension (longitudinal direction) is provided to the substrate FS at least between the roller CR2 and the roller CR3 while setting the conveyance speed of the substrate FS as a target value. The tension of the seat substrate FS can be obtained by providing a load cell or the like for measuring a force that pushes up the air turn bar TB1, TB2 in the Z-axis direction, for example.

Further, the mount EQ1 (and the supply roll RL1, the roller CR1) have the function of slightly moving in the range on the order of ±several mm in the Y-axis direction by a servomotor or the like, in accordance with detection results from an edge sensor ES1 that measures variations in the Y-axis direction (the width direction perpendicular to the longitudinal direction of the sheet substrate FS) in edge (end) positions on both sides of the sheet substrate FS immediately before reaching the air turn bar TB1, that is, the EPC (edge position control) function. Thus, even when the sheet substrate rolled up around the supply roll RL1 has uneven winding in the Y-axis direction, the center position in the Y-axis direction of the sheet substrate FS passing the roller CR2 always has a variation reduced within a certain range (e.g., ±0.5 mm). Therefore, the sheet substrate FS accurately positioned with respect to the width direction is carried into the film formation main body (second chamber 12).

Likewise, the mount EQ2 (and the collection roll RL2, the roller CR4) have the EPC function of slightly moving in the range on the order of ±several m in the Y-axis direction by a servomotor or the like, in accordance with detection results from an edge sensor ES2 that measures variations in the Y-axis direction in edge (end) positions on both sides of the sheet substrate FS immediately after passing the air turn bar TB2. Thus, the sheet substrate FS subjected to film formation is rolled up around the collection roll RL2, while being prevented from undergoing uneven winding in the Y-axis direction. Further, the mounts EQ1 and EQ2, the supply roll RL1, the collection roll RL2, the air turn bars TB1 and TB2, and the rollers CR1, CR2, CR3 and CR4 have a function as a conveying unit for guiding the substrate FS to the mist supply units 22 (22A, 22B).

In the device of FIG. 19, the rollers CR2 and CR3 are arranged such that the linear conveying path of the sheet substrate FS in the film forming main body (the second chamber 12) is inclined and thus increased by on the order of 45°±15° (here, 45°) in the conveying direction of the substrate FS. Due to this inclination of the conveying path, mists of the dispersion liquid 63 sprayed onto the sheet substrate FS by a mist deposition method or a mist CVD method can be retained to a moderate degree on the surface of the sheet substrate FS, thereby improving the deposition efficiency (also referred to as film formation rate or film formation speed) of the particles 66. While the configuration of the film formation main body will be described later, the substrate FS is inclined in the longitudinal direction in the second chamber 12, the orthogonal coordinate system Xt⋅Y⋅Zt is thus set with a plane parallel to the surface to be processed of the substrate FS as a Y⋅Xt plane, and with a direction perpendicular to the Y⋅Xt plane as Zt.

According to the present embodiment, two mist supply units 22A, 22B are provided in the second chamber 12 at a regular interval in the conveying direction (Xt direction) of the substrate FS. The mist supply units 22A and 22B are formed in a cylindrical shape, and on the tip sides opposed the substrate FS, slit-like apertures elongated in the Y-axis direction are provided for ejecting a mist gas (a mixed gas of a gas and a mist) Mgs toward the substrate FS. Furthermore, a pair of parallel wire-like electrodes 24A and 24B for generating atmospheric pressure plasma in a non-thermal equilibrium state is provided near the apertures of the mist supply units 22A and 22B. A pulse voltage from the high-voltage pulse power supply unit 40 is applied to the pair of electrodes 24A, 24B each at a predetermined frequency.

The type of the gas as a plasma source for generating the plasma in the mist supply units 22A and 22B is not particularly limited, and known gases can be used. Specific examples of the gas include helium, argon, xenon, oxygen, and nitrogen. Among these examples, helium, argon, and xenon with high stability are preferred. In addition, the gas used to generate plasma in the mist generation units 20A and 20B can be used as it is in the mist supply units 22A and 22B as the gas used to generate plasma. This allows reduction in the amount of gas used in the film formation device as a whole, thereby reducing costs.

In addition, temperature controllers 23A, 23B for maintaining the internal spaces of the mist supply units 22A, 22B at a set temperature are provided on the outer periphery of the mist supply units 22A, 22B. The temperature controllers 23A and 23B are controlled by a temperature control unit 28 so as to reach a set temperature.

The mist gas Mgs of the dispersion liquid 63 generated in the first mist generation unit 20A and the second mist generation unit 20B is supplied at a predetermined flow rate to each of the mist supply units 22A and 22B via the ducts 21A and 21B. The mist gas Mgs of the dispersion liquid 63 ejected from the slit-like apertures of the mist supply units 22A, 22B in the −Zt-axis direction is blown onto the upper surface of the substrate FS at a predetermined flow rate, and thus allowed to flow immediately downward (−Z-axis direction) as it is. In order to extend the residence time of the mist gas of the dispersion liquid 63 on the upper surface of the substrate FS, the gas in the second chamber 12 is suctioned by an exhaust control unit 30 via a duct 12C.

More specifically, the creation of a flow of gas from the slit-like apertures of the mist supply units 22A, 22B toward the duct 12C in the second chamber 12 controls the mist gas Mgs of the dispersion liquid 63 from flowing from the upper surface of the substrate FS immediately downward (−Z-axis direction).

The exhaust control unit 30 removes the particles 66 or a gas, included in the suctioned gas in the second chamber 12, to produce a clean gas (air), and then discharges the gas into the environment via a duct 30A. It is to be noted that while the mist generation units 20A, 20B are provided outside the second chamber 12 (inside the first chamber 10) in FIG. 19, for reducing the volume of the second chamber 12, thereby making it easier to control the flow of gas (flow rate, flow speed, flow path, etc.) in the second chamber 12 when the gas is suctioned by the exhaust control unit 30. Of course, the mist generation units 20A and 20B may be provided inside the second chamber 12.

In the case of depositing a film on the substrate FS by a mist CVD method with the use of the mist gas Mgs of the dispersion liquid 63 from each of the mist supply units 22A and 22B, it is necessary to set the substrate FS at a temperature higher than normal temperature, for example, about 200° C. Therefore, according to the present embodiment, a substrate temperature control units 27A and 27B are provided in positions (the back side of the substrate FS) opposed to the respective slit-like apertures of the mist supply units 22A, 22B with the substrate FS therebetween, and controlled by the temperature control unit 28 such that the temperature of a region on the substrate FS where the mist gas Mgs of the dispersing liquid 63 is ejected reaches the set value. On the other hand, in the case of film formation by a mist deposition method, it is not necessary to operate the substrate temperature control units 27A, 27B because normal temperature may be adopted, but when it is desirable to set the substrate FS to a temperature lower than normal temperature (for example, 40° C. or lower), the substrate temperature control units 27A and 27B can be operated as appropriate.

The mist generation units 20A, 20B, the temperature control unit 28, the exhaust control unit 30, the high-voltage pulse power supply unit 40, and the motor control unit (the control system for the servomotors that rotationally drive the supply roll RL1 and the collection roll RL2), and the like are controlled by a main control unit 100 including a computer in an integrated manner.

[Sheet Substrate]

Next, the sheet substrate FS as an object to be processed will be described. As described above, for example, a resin film, or foil (foil) made of a metal or an alloy such as stainless steel, or the like is used for the substrate FS. As the material of the resin film, a material may be used which includes one, or two or more resins, for example, among a polyethylene resin, a polypropylene resin, a polyester resin, an ethylene vinyl copolymer resin, a polyvinyl chloride resin, a cellulose resin, a polyamide resin, a polyimide resin, a polycarbonate resin, a polystyrene resin, and a vinyl acetate resin. In addition, the thickness and rigidity (Young's modulus) of the substrate FS have only to fall within such a range as not to cause the substrate FS to have folds or irreversible wrinkles due to buckling when the substrate FS is conveyed. An inexpensive resin sheet such as PET (polyethylene terephthalate) or PEN (polyethylene naphthalate) on the order of 25 μm to 200 μm in thickness is used in the case of creating flexible display panels, touch panels, color filters, electromagnetic wave prevention filters, and the like as electronic devices.

For example, the substrate FS which is not significantly large in coefficient of thermal expansion is desirably selected so as to achieve a substantially negligible amount of deformation due to heat applied in various types of processing applied to the substrate FS. In addition, when an inorganic filler such as titanium oxide, zinc oxide, alumina, or silicon oxide, for example, is mixed with the resin film as a base, the coefficient of thermal expansion can be reduced. Further, the substrate FS may be a single-layer body of ultrathin glass on the order of 100 μm in thickness manufactured by a float method or the like, or a single-layer body of a metal sheet obtained by rolling a metal such as stainless steel into a thin film shape, or may be a laminated body obtained by attaching the resin film mentioned above, a metal layer (foil) such as aluminum or copper, or the like to the ultrathin glass or the metal sheet. Furthermore, in the case of film formation by a mist deposition method with the use of the thin film manufacturing device 1 according to the present embodiment, the temperature of the substrate FS can be set to 100° C. or lower (typically on the order of normal temperature), but in the case of film formation by the mist CVD method, it is necessary to set the temperature of the substrate FS to on the order of 100° C. to 200° C. Therefore, in the case of film formation by a mist CVD method, a substrate material (for example, polyimide resin, ultrathin glass, metal sheet, etc.) is used which undergoes no deformation or alteration even at a temperature on the order of 200° C.

Now, the flexibility (flexibility) of the substrate FS refers to the property that it is possible to make the substrate FS flexible without any disconnection or fracture, even when the substrate FS has a force on the order of its own weight applied thereto. In addition, the flexibility also encompasses the property of being flexed by the force on the order of its own weight. In addition, the degree of flexibility varies depending on the material, size, and thickness of the substrate FS, the layer structure formed on the substrate FS, environments such as temperature and humidity, and the like. In any case, as long as the substrate FS can be conveyed smoothly without any buckling resulting in the formation of folds or breakage (generation of tears or cracks) when the substrate FS is wound correctly around various types of conveying rollers, turn bars, rotating drums, etc. provided in the conveying path of the thin film manufacturing device 1 according to the present embodiment or a manufacturing device that controls processes before and after the thin film manufacturing device 1, it can be said to fall within the scope of flexibility.

It is to be noted that the substrate FS supplied from the supply roll RL1 shown in FIG. 19 may be a substrate in intermediate process. More specifically, a specific layer structure for electronic devices may be formed already on the surface of the substrate FS rolled up around the supply roll RL1. The layer structure refers to a single layer such as a resin film (insulating film) or a metal thin film (copper, aluminum, etc.) formed to have a certain thickness on the surface of the sheet substrate as a base, or a multilayer structure of the films thereon. Further, as disclosed in, for example, WO2013/176222, the substrate FS to which a mist deposition method is applied in the thin film manufacturing device 1 in FIG. 19 may have a surface condition provided with a large difference in lyophilic/lyophobic property with respect to the mist liquid between parts irradiated or non-irradiated with ultraviolet light, by applying a photosensitive silane coupling material on the surface of the substrate, drying the material, and then irradiating the material with ultraviolet light (with a wavelength of 365 nm or less) in accordance with a distribution corresponding to the shape of a pattern for electronic devices through the use of an exposure device. In this case, a mist adheres to the hydrophilic part of the irradiated or non-irradiated parts, and the mist can be attached selectively to the surface of the substrate FS in accordance with the shape of the pattern by a mist deposition method with the use of the thin film manufacturing device 1 of FIG. 1.

Furthermore, the long sheet substrate FS supplied to the thin film manufacturing device 1 of FIG. 19 may have a resin sheet or the like of a standard size corresponding to the size of an electronic device to be manufactured, attached to the surface of a long thin metal sheet (for example, a SUS belt on the order of 0.1 mm in thickness) at a regular interval in the longitudinal direction of the metal sheet. In this case, the object to be processed, subjected to film formation by the thin film manufacturing device 1 of FIG. 19 is a resin sheet that has a standard size.

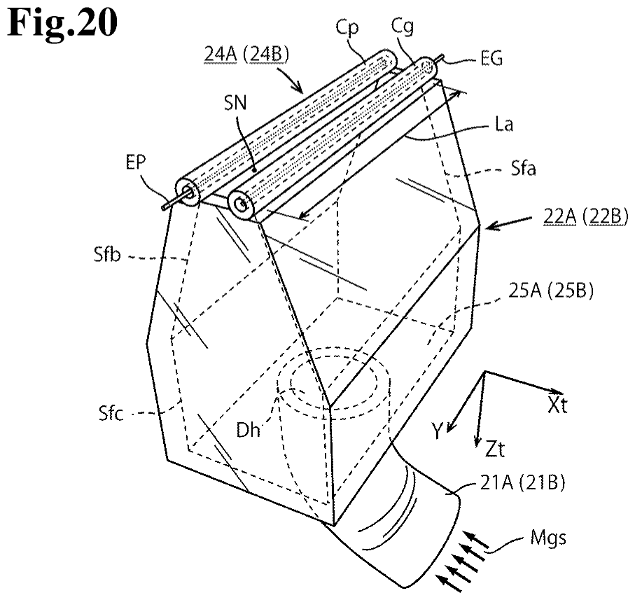

Next, the configurations of respective units in the thin film manufacturing device 1 in FIG. 19 will be described with reference to FIGS. 20 to 24 along with FIG. 19.

[Mist Supply Units 22A, 22B]

FIG. 20 is an example of the perspective view of the mist supply unit 22A (as well as 22B) as viewed from the −Zt side of the coordinate system Xt⋅Y⋅Zt, that is, from the substrate FS side. The mist supply unit 22A is composed of a quartz plate, which has inclined inner walls Sfa, Sfb with a fixed length in the Y direction, and with a width in the Xt direction gradually decreased in the −Zt direction, inner walls Sfc of side surfaces parallel to the Xt-Zt surface, and a top board 25A (25B) parallel to the Y-Xt surface. The duct 21A (21B) from the mist generation unit 20A (20B) is connected to an aperture Dh in the top board 25A (25B), and the mist gas Mgs is supplied into the mist supply unit 22A (22B). The mist supply unit 22A (22B) has, at the tip thereof in the −Zt-axis direction, a slot-like aperture SN formed, which is elongated in the Y-axis direction over a length La, and the pair of electrodes 24A (24B) is provided so as to sandwich the aperture SN in the Xt direction. Therefore, the mist gas Mgs (positive pressure) supplied into the mist supply unit 22A (22B) through the aperture Dh is passed through the space between the pair of electrodes 24A (24B) from the slot-like aperture SN, and ejected with a uniform flow rate distribution in the −Zt-axis direction.

The pair of electrodes 24A is composed of a wire-like electrode EP extending in the Y direction in excess of a length La, and a wire-like electrode EG extending in the Y direction in excess of the length La. The electrodes EP and EG are respectively held in a cylindrical quartz tube Cp1 that functions as a dielectric Cp and a quartz tube Cg1 that functions as a dielectric Cg so as to be parallel at a predetermined interval in the Xt direction, and fixed to the tips of the mist supply unit 22A (22B) so that the quartz tubes Cp1, Cg1 are located on both sides of the slot-like aperture SN. The quartz tubes Cp1 and Cg1 desirably contain therein no metal component. In addition, the dielectrics Cp and Cg may be tubes made of ceramics that are high in dielectric strength voltage.

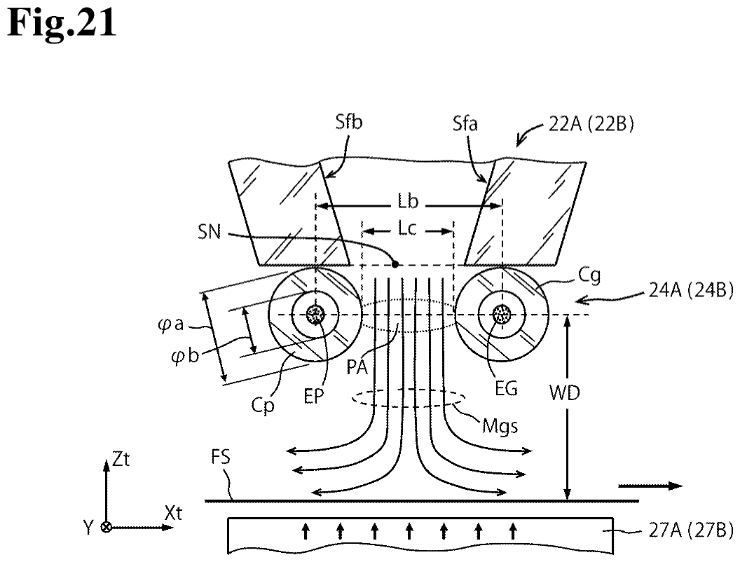

FIG. 21 is an example of the cross-sectional view of a tip of the mist supply unit 22A (22B) and the pair of electrodes 24A (24B) as viewed from the Y-axis direction. According to the present embodiment, as an example, the outer diameter φa of the quartz tubes Cp1, Cg1 is set to about 3 mm, whereas the inner diameter φb thereof is set to about 1.6 mm (wall thickness: 0.7 mm), and the electrodes EP, EG are composed of wires of 0.5 nm to 1 mm in diameter, made from low-resistance metal such as tungsten or titanium. The electrodes EP and EG are held by insulators at both ends of the quartz tubes Cp1, Cg1 in the Y direction so as to pass linearly through the centers of the inner diameters of the quartz tubes Cp1, Cg1. It is to be noted that there has only to be any one of the quartz tubes Cp1, Cg1, and for example, the electrode EP connected to a positive electrode of the high-voltage pulse power supply unit 40 may be surrounded by the quartz tube Cp1, whereas the electrode EG connected to a negative electrode (ground) of the high-voltage pulse power supply unit 40 may be exposed. However, because the exposed electrode EG is contaminated or corroded depending on the gas component of the mist gas Mgs ejected from the aperture SN at the tip of the mist supply unit 22A (22B), the electrodes EP, EG are preferably both surrounded by the quartz tube Cp1, Cg1, that is, configured such that the mist gas Mgs are not brought into direct contact with the electrodes EP, EG.

In this regard, each of the wire-like electrodes EP and EG is disposed in parallel to the surface of the substrate FS in a position at a height of working distance (working distance) WD from the surface of the substrate FS, and disposed at an interval Lb in the conveying direction (Xt direction) of the substrate FS. The interval Lb is set to be as narrow as possible in order to generate atmospheric pressure plasma in a non-thermal equilibrium state continuously in a stable manner in a uniform distribution in the −Zt-axis direction, and set to on the order of 5 mm as an example. Therefore, the effective width (gap) Lc in the Xt direction is Lc=Lb−φa when the mist gas Mgs injected from the aperture SN of the mist supply unit 22A (22B) passes between the pair of electrodes, and when a quartz tube of 3 mm in outer diameter is used, the width Lc is about 2 mm.

Furthermore, although not essential, it is preferable to make the working distance WD larger as compared with the interval Lb in the Xt-axis direction between the wire-like electrodes EP, EG. This is because if there is an arrangement relationship of Lb>WD, there is a possibility that plasma will be generated between the electrode EP (quartz tube Cp1) which serves as a positive electrode and the substrate FS, or arc discharge will be caused therebetween.

In other words, the working distance WD, which is the distance from the electrodes EP, EG to the substrate FS, is desirably longer than the interval Lb between the electrodes EP, EG.

However, when the potential of the substrate FS can be set between the potential of the electrode EG which serves as a grounding electrode and the potential of the electrode EP which serves as a positive electrode, it is also possible to set Lb>WD.

It is to be noted that there is no need for the plane formed by the electrode 24A and the electrode 24B to be parallel to the substrate FS. In that case, the distance from a part of the electrodes closest to the substrate FS to the substrate FS is regarded as the working distance WD, and the installation position of the mist supply unit 22A (22B) or the substrate FS is adjusted.

In the case of the present embodiment, the plasma in the non-thermal equilibrium state is strongly generated in a region with the narrowest interval between the pair of electrodes 24A (24B), that is, in a limited region PA in the Zt-axis direction with the width Lc in FIG. 21. Therefore, reducing the working distance WD comes to be able to shorten the time from when the mist gas Mgs is irradiated with the plasma in the non-thermal equilibrium state until when the mist gas Mgs reaches the surface of the substrate FS, and the film formation rate (deposition film thickness per unit time) can be expected to be improved. In FIG. 21, the interval Lb in the Xt direction between wire-like electrodes EP and EG may be set from 10 μm to 20 mm from the viewpoint of plasma generation efficiency. The lower limit is preferably 0.1 mm, more preferably 1 mm. The upper limit is preferably 15 mm, more preferably 10 mm.

When the interval Lb (or width Lc) between the pair of electrodes 24A (24B) and the working distance WD are not changed, the film formation rate is changed by the peak value and frequency of the pulse voltage applied between the electrodes EP, EG, the flow rate (speed) of the mist gas Mgs ejected from the aperture SN, the concentrations of specific substances (particles, molecules, ions, etc.) for film formation, included in the mist gas Mgs, or the controlled temperature of the substrate temperature control unit 27A (27B) placed on the back side of the substrate FS, etc., and these conditions are thus adjusted appropriately by the main control unit 100, depending on the type of a specific substance to be deposited on the substrate FS, the thickness of the film formation, the flatness, etc.

(High-Voltage Pulse Power Supply Unit 40)

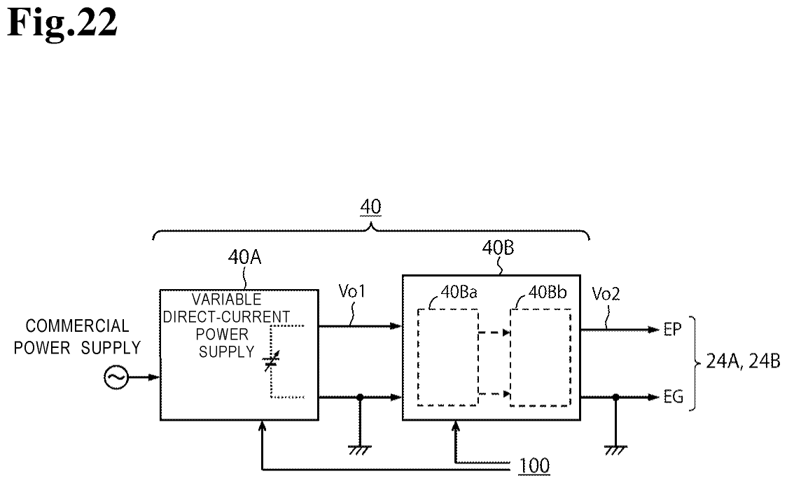

FIG. 22 is a block diagram illustrating an example of a schematic configuration of the high-voltage pulse power supply unit 40, which is composed of a variable direct-current power supply 40A and a high-voltage pulse generation unit 40B. The variable direct-current power supply 40A inputs a commercial alternating-current power supply of 100 V or 200 V, and outputs a smoothed direct-current voltage Vo1. The voltage Vo1 is made variable between 0 V and 150 V, for example, and also referred to as a primary voltage since the voltage serves as a power supply to the high-voltage pulse generation unit 40B in the next stage. The high-voltage pulse generation unit 40B is provided therein with a pulse generation circuit section 40Ba that repeatedly generates a pulse voltage (a rectangular short pulse wave whose peak value is approximately the primary voltage Vo1) corresponding to the frequency of the high-voltage pulse voltage applied between the wire-like electrodes EP, EG, and a boosting circuit section 40Bb that generates, in response to the pulse voltage, a high-voltage pulse voltage whose rise time and pulse duration are extremely short as an inter-electrode voltage Vo2.

The pulse generation circuit section 40Ba is composed of a semiconductor switching element and the like which turn on/off the primary voltage Vo1 at high speed at a frequency f. The frequency f is set to several KHz or less, but the rise time/fall time of the pulse waveform obtained by switching is set to several tens nS or less, and the pulse duration is set to several hundreds nS or less. The boosting circuit section 40Bb is intended to boost such a pulse voltage by about 20 times, and composed of a pulse transformer or the like.

The pulse generation circuit section 40Ba and the boosting circuit section 40Bb, by way of example only, may have any configuration as long as a pulse voltage with a peak value on the order of 20 kV, pulse rise time of about 100 nS or less, and a pulse duration of several hundreds nS or less can be continuously generated at the frequency f of several kHz or less as the final inter-electrode voltage Vo2. The higher the inter-electrode voltage Vo2 is, the larger the interval Lb (and the width Lc) between the pair of electrodes 24A (24B) shown in FIG. 20 is allowed to be, thereby making it possible to expand, in the Xt direction, the region on the substrate FS where the mist gas Mgs is ejected, and thus increase the film formation rate.

Further, in order to adjust the generation of plasma in a non-thermal equilibrium state between the pair of electrodes 24A (24B), the variable direct-current power supply 40A has such a function of varying the primary voltage Vo1 (i.e., an inter-electrode voltage Vo2) in response to an instruction from the main control unit 100, and the high-voltage pulse generation unit 40B has such a function of varying the frequency f of the pulse voltage applied between the pair of electrodes 24A (24B) in response to an instruction from the main control unit 100.

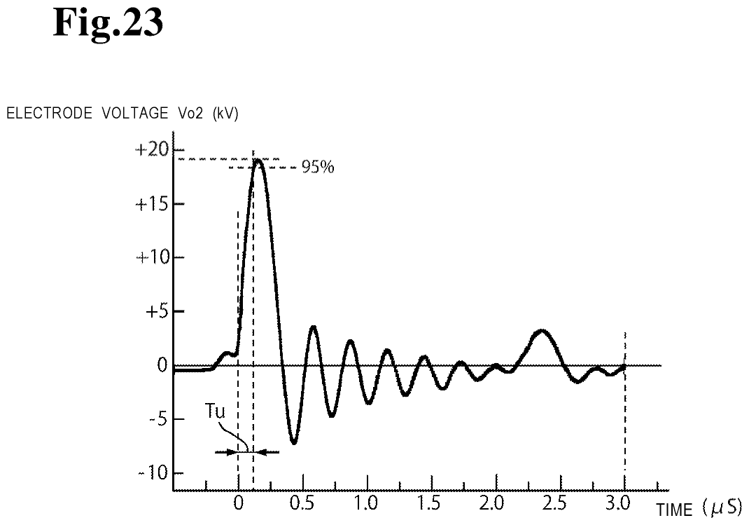

FIG. 23 shows an example of waveform characteristics of the inter-electrode voltage Vo2 obtained by the high-voltage pulse power supply unit 40 configured as shown in FIG. 22, where the vertical axis represents a voltage Vo2 (kV) and the horizontal axis represents time (μS). The characteristics in FIG. 23 show the waveform of one pulse of the inter-electrode voltage Vo2 obtained in the case of the primary voltage Vo1 of 120 V and the frequency f of 1 kHz, where a pulse voltage Vo2 of about 18 kV is obtained as a peak value. Furthermore, the rise time Tu from 5% to 95% of the first peak value (18 kV) is about 120 nS. In addition, in the circuit configuration of FIG. 22, a ringing waveform (attenuation waveform) is generated up to 2 μS after the waveform (pulse duration is about 400 nS) at the first peak value, but the voltage waveform at this part never lead to the generation of plasma in a non-thermal equilibrium state or arc discharge.

In the case of the previously exemplified configuration example of the electrodes, or of placing the electrodes EP, EG covered with the quartz tubes Cp1, Cg1 of 3 mm in outer diameter and 1.6 mm in inner diameter at the interval Lb=5 mm, the waveform part at the first peak value as shown in FIG. 23 is repeated at the frequency f, thereby stably and continuously generating atmospheric pressure plasma in a non-thermal equilibrium state is in the region PA (FIG. 21) between the pair of electrodes 24A (24B).

(Substrate Temperature Control Unit 27A, 27B)

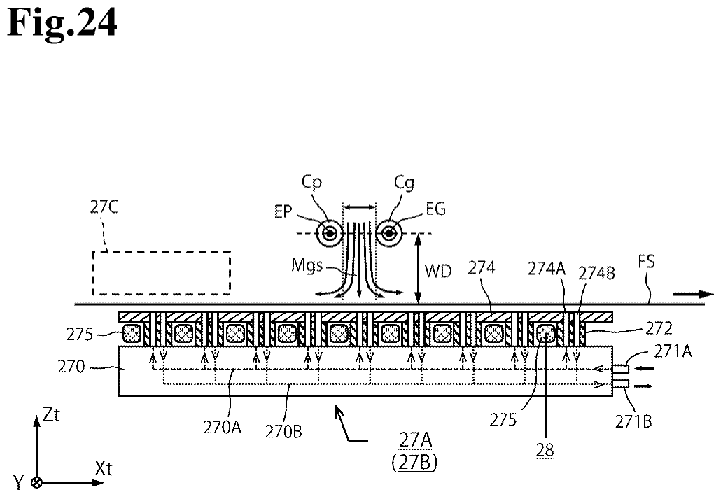

FIG. 24 is a cross-sectional view illustrating an example of the configuration of a substrate temperature control unit 27A (as well as 27B) in FIG. 19. Since the sheet substrate FS is continuously conveyed at a constant speed (for example, several mm to several cm per minute) in the longitudinal direction (Xt-axis direction), there is a possibility of scratching the back surface of the substrate FS, with the upper surface of the substrate temperature control unit 27A (27B) in contact with the back surface of the sheet substrate FS. Thus, according to the present embodiment, a gas layer of air bearing with a thickness on the order of several μm to several tens μm is formed between the upper surface of the substrate temperature control unit 27A (27B) and the back surface of the substrate FS such that the substrate FS is fed in a non-contact state (or low friction state).

The substrate temperature control unit 27A (27B) is composed of a base 270 opposed to the back surface of the substrate FS, spacers 272 at a fixed height, provided in multiple locations on the base 270 (Zt-axis direction), a flat metallic plate 274 provided on the plurality of spacers 272, and a plurality of substrate temperature controllers 275 provided between the plurality of spacers 272, and between the base 270 and the plate 274.

The plurality of spacers 272 is each formed with a gas ejection hole 274A that penetrates up to the surface of the plate 274 and an air suction hole 274B for gas suction. The ejection hole 274A penetrating through each spacer 272 is connected to a gas introduction port 271A via a gas flow path formed in the base 270, and the air suction hole 274B penetrating through each spacer 272 is connected to a gas exhaust port 271B through a gas flow path formed in the base 270. The introduction port 271A is connected to a source of pressurized gas supply, and the exhaust port 271B is connected to a reduced pressure source for creating a vacuum pressure.

The surface of the plate 274 is provided with the ejection hole 274A and the air suction hole 274B close to each other within the Y-Xt plane, the gas ejected from the ejection hole 274A is thus immediately suctioned into the air suction hole 274B. Thus, a gas layer of air bearing is formed between the flat surface of the plate 274 and the back surface of the substrate FS. When the substrate FS is conveyed with predetermined tension in the longitudinal direction (Xt-axis direction), the substrate FS keeps itself flat to follow the surface of the plate 274.

Additionally, since the gap between the surface of the plate 274 temperature-controlled by the plurality of substrate temperature controllers 275 and the back surface of the substrate FS is only about several μm to several tens μm, the substrate FS is immediately adjusted to a set temperature by radiant heat from the surface of the plate 274. The set temperature is controlled by the temperature control unit 28 shown in FIG. 19.

In addition, when there is a need for temperature-controlling not only from the back surface of the substrate FS but also from the upper surface (processed surface) side, a temperature-controlling plate (the set of plate 274 and substrate temperature controller 275 in FIG. 24) 27C opposed to the upper surface of the substrate FS at a predetermined gap is provided upstream of the region where the mist gas Mgs is ejected with respect to the conveying direction of the substrate FS.

As described above, the substrate temperature control unit 27A (27B) has both a temperature control function of temperature-controlling a part of the substrate FS subjected to the jet of mist gas Mgs, and a non-contact (low friction) support function of floating the substrate FS by the hair bearing method, and thus supporting the substrate FS to be flat. The working distance WD in the Zt direction between the upper surface of the substrate FS and the pair of electrodes 24A (24B) as shown in FIG. 23 is desirably kept constant even in the process of conveying the substrate FS in order to maintain the film thickness uniformity during film formation. As shown in FIG. 24, since the substrate temperature control unit 27A (27B) according to the present embodiment supports the substrate FS with vacuum pressurized air bearing, the gap between the back surface of the substrate FS and the upper surface of the plate 274 is kept substantially constant, thereby suppressing the positional fluctuation of the substrate FS in the Zt direction.

As just above, in the thin film manufacturing device 1 configured according to the present embodiment (FIGS. 19 to 24), while the substrate FS is conveyed at a constant speed in the longitudinal direction, the high-voltage pulse power supply unit 40 is operated to generate atmospheric pressure plasma in a non-thermal equilibrium state between the pair of electrodes 24A, 24B, and the mist gas Mgs is ejected at a predetermined flow rate from the aperture SN between the mist supply units 22A, 22B. The mist gas Mgs that has passed through the region PA (FIG. 21) where atmospheric pressure plasma is generated is ejected to the substrate FS, and the specific substance the mist of the mist gas Mgs contains therein is continuously deposited on the substrate FS.

According to the present embodiment, the arrangement of the two mist supply units 22A, 22B in the conveying direction of the substrate FS doubly improves the film formation rate of a thin film of the specific substance deposited on the substrate FS. Therefore, the film formation rate is further improved by increasing the mist supply units 22A, 22B in the conveying direction of the substrate FS.

Further, according to the present embodiment, the mist generation units 20A and 20B are individually provided respectively for the mist supply units 22A and 22B, and the substrate temperature control units 27A and 27B are individually provided therefor. Therefore, the mist gas Mgs ejected from the aperture SN of the mist supply unit 22A and the mist gas Mgs ejected from the aperture SN of the mist supply unit 22B can be varied in properties (the content concentration of a specific substance in the precursor LQ, the ejection flow rate and temperature of the mist gas, etc.), and the temperature of the substrate FS can be varied. The film formation conditions (film thickness, flatness, etc.) can be adjusted by varying the properties of the mist gas Mgs ejected from the aperture SN for each of the mist supply units 22A, 22B and the temperature of the substrate FS.

Since the thin film manufacturing device 1 in FIG. 19 is intended to convey the substrate FS independently by the roll-to-roll method, the film formation rate can be adjusted also by changing the conveyance speed of the substrate FS. However, it may be difficult to change the conveyance speed of the substrate FS in some cases, when a pre-process device is connected which applies base processing or the like to the substrate FS before forming a film by the thin film manufacturing device 1 as in FIG. 19, or when a post-process device is connected which applies a treatment such as applying a photosensitive resist, a photosensitive silane coupling material, or the like immediately to the substrate FS with the film formed. Even in such a case, the thin film manufacturing device 1 according to the present embodiment can adjust the film formation conditions, so as to be suitable for the set conveyance speed of the substrate FS.

Of course, the mist gas Mgs generated by one mist generation unit 20A may be distributed and supplied to each of the two mist supply units 22A, 22B, or more mist supply units.

It is to be noted that while the configuration for supplying the mist gas Mgs to the substrate FS from the Zt-axis direction has been described in the present embodiment, the present invention is not limited thereto, but any configuration for supplying the mist gas Mgs to the substrate FS from the −Zt direction may be adopted. In the case of a configuration for supplying the mist gas Mgs to the substrate from the Zt direction, there is a possibility that the droplets accumulated in the mist supply units 22A, 22B will fall onto the substrate FS, which can be suppressed by adopting a configuration for supplying the mist gas Mgs to the substrate FS from the −Zt-axis direction. Which direction the mist gas Mgs is supplied from may be determined appropriately depending on the supply amount of the mist gas Mgs and other manufacturing conditions.

### Eighth Embodiment

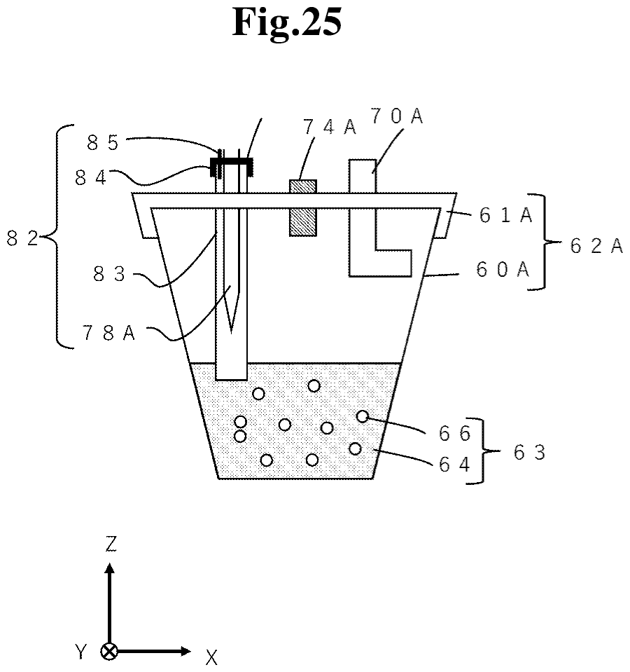

An eighth embodiment will be described with reference to FIG. 25. FIG. 25 is a schematic diagram showing an example of a mist generator 90 according to the eighth embodiment. Each configuration according to the eighth embodiment is considered the same as that according to the first embodiment, unless otherwise described. It is to be noted that the mist generators 90 in the embodiment and modification examples thereof, shown in FIGS. 25 to 28 each includes an external container 91 and a misting unit 80, which are similar to those of the embodiment described above. In the examples shown below, the illustration of the misting unit 80 and external container 91 is omitted, unless otherwise noted.

The mist generator 90 according to the present embodiment includes a plasma generation unit 82. The plasma generation unit 82 includes a hollow body 83, a plug 84, and a gas introduction part 85 in addition to the electrode 78A described above. The hollow body 83 is a member with a hollow inside for surrounding at least a part of the electrode.

The hollow body 83 has one end located below the liquid level of a dispersion liquid 63, and opened. The other end thereof is closed, and the inside of the hollow body 83 is filled with a gas. As an example, the other end of the hollow body 83 is sealed with the plug 84 through which the electrode 78A is inserted. In addition, the hollow body may have a structure with the other end itself of the hollow body closed, instead of the structure sealed with the plug. In the example shown in FIG. 25, the hollow body 83 penetrates the lid part 61A. More specifically, the plug 84 is located outside a container 62A.

The hollow body 83 is formed from an insulating material such that the plasma generated from the electrode 78A is stably output to the dispersion liquid 63. The hollow body 83 is formed from, for example, glass, quartz, a resin, or the like. It is to be noted that the hollow body 83 is preferably formed from a heat-resistant material, because there is a possibility of heat generation in generating plasma from the electrode 78A. In addition, for confirming that the plasma is stably generated with respect to the liquid level of the dispersion liquid 63, the hollow body may be formed from a material with permeability. From this point of view, the hollow body 83 is more preferably formed from glass or quartz.

The gas introduction part 85 introduces a gas into the hollow body 83. As an example, the gas introduction part 85 penetrates the plug 84. The gas introduced by the gas introduction part 85 is used to irradiate the liquid level of the dispersion liquid 63 stably with the plasma generated by the electrode 78A. Specific examples of the gas include helium, argon, xenon, oxygen, nitrogen, and air. Among these examples, at least one of highly stable helium, argon, and xenon is preferably contained.

The position of the gas introduction part 85 placed is not limited to the position shown in FIG. 25. For example, the wall surface of the hollow body 83 may be provided with a gas introduction port that functions as the gas introduction part 85. The gas introduction part 85 may be provided outside the container 62A or may be provided inside the container 62A.

Even when the inside of the hollow body 83 is filled with a gas, with the upper end thereof sealed with the plug 84, there is a possibility that a minute amount of gas leaks out from the inside of the hollow body 83, for example, in a case where the sealing is not completely achieved. The introduction of the gas from the gas introduction part 85 is intended to supplement the leaking gas, and the gas is introduced to such an extent that no gas exits from the opening at the lower end of the hollow body 83. It is to be noted that the gas introduction part 85 is not an essential component in the present embodiment.

Although the mist generator 90 shown in FIG. 25 has one hollow body 83 surrounding one electrode 78A, the numbers of hollow bodies 83 and electrodes 78A included in the mist generator 90 are not limited thereto. The mist generator 90 may include a plurality of plasma generation units 82 with one hollow body 83 surrounding one electrode 78A. More specifically, the container 62A may have therein a plurality of hollow bodies 83 each with one electrode 78A. In addition, one or more hollow bodies 83 included in the mist generator 90 may have a plurality of electrodes 78A.

The mist generator 90 has a plurality of electrodes 78A surrounded by the hollow body 83, thereby increasing the plasma intended to irradiate the liquid level, and allowing the dispersibility of the particles 66 in the dispersion liquid 63 to be enhanced.

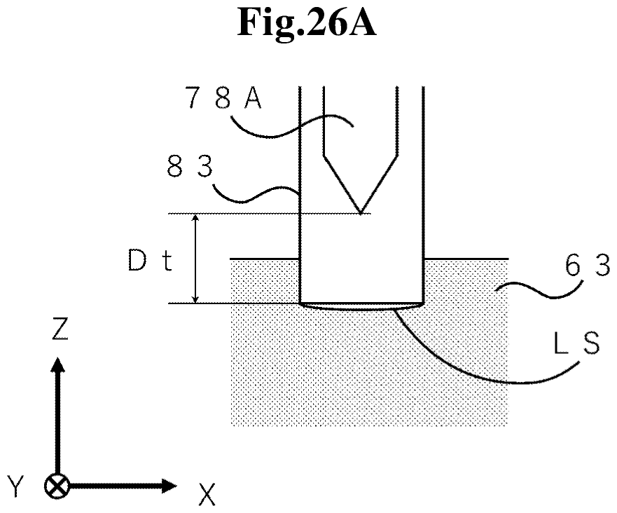

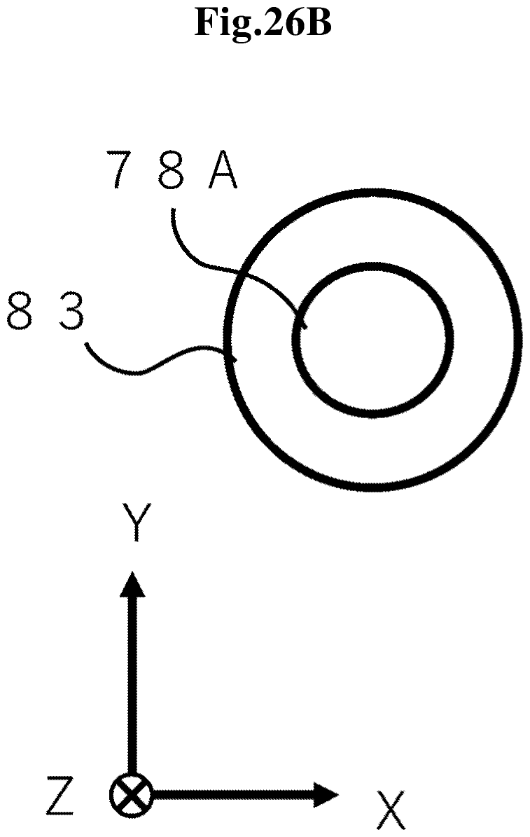

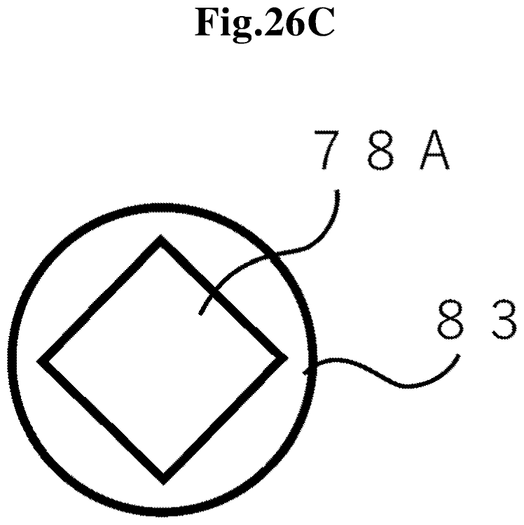

FIG. 26 is a diagram for illustrating an outline of the plasma generation unit 82. FIG. 26A is an example of the appearance of a tip part of the plasma generation unit 82, and FIG. 26B is an example (part 1) of a cross-sectional view (top view) of the plasma generation unit 82. FIG. 26C is an example (part 2) of a cross-sectional view (top view) of the plasma generation unit 82.

The shape of the electrode 78A according to the present embodiment is not limited to the example shown in FIG. 26, as in the embodiment described above. For example, the electrode 78A may be the electrode 78B or electrode 78C shown in FIG. 2. From the viewpoint of the plasma generation efficiency, the electrode 78A according to the present embodiment preferably, as in the first embodiment shown in FIG. 2, has a reduced area at the tip of the electrode 78A, which is the part closest to the liquid level.

As shown in FIG. 26A, a liquid level LS to serve as a boundary between the gas inside the hollow body 83 and the dispersion liquid 63 is located at the opening part at the tip of the hollow body 83. The electrode 78A is provided at a position with the tip out of contact with the liquid level LS of the dispersion liquid 63. In the mist generator 90, the dispersion liquid 63 is desirably irradiated stably with plasma from the electrode 78A for improving the dispersibility of the particles 66. The long distance between the liquid level LS of the dispersion liquid 63 and the tip of the electrode 78A impairs the stability of the plasma irradiation. The upper limit of the distance Dt between the tip of the electrode 78A and the lower end of the hollow body 83 is preferably 30 mm, more preferably 25 mm.

In addition, the short distance between the liquid level LS of the dispersion liquid 63 and the tip of the electrode 78A has the possibility of causing the liquid level LS and the tip of the electrode 78A to come into contact with each other, for example, when the liquid level LS waves. The lower limit of the distance Dt between the tip of the electrode 78A and the lower end of the hollow body 83 is preferably 10 mm, more preferably 15 mm.

When the liquid level of the dispersion liquid 63 in the container 62A waves due to the mist generation of the misting unit, the distance between the tip of the electrode 78A and the liquid level varies, thereby impairing the stability of the plasma irradiation, and deteriorating the dispersibility of the particles 66. With the hollow body 83 surrounding the periphery of the electrode 78A, the tip of the hollow body 83 is provided below the liquid level of the dispersion liquid 63, thereby keeping the liquid level LS from waving, and allowing the dispersion liquid 63 to be stably irradiated with plasma.

In addition, as shown in FIG. 26A, the hollow body 83 can be filled with a gas such that the liquid level LS protrudes downward from the tip of the hollow body 83. The surface tension of the liquid level LS keeps the liquid level LS from waving when the misting unit generates a mist, thus allowing the dispersion liquid 63 to be stably irradiated with plasma, and allowing the dispersibility of the particles 66 in the dispersion liquid 63 to be enhanced.

FIGS. 26B and 26C are examples of cross-sectional views of the plasma generation unit 82 viewed from the Z-axis direction. The cross section of the hollow body 83 and the cross section of the electrode 78A, shown in FIG. 26B, are substantially circular. The cross section of hollow body 83 shown in FIG. 26C is substantially circular, and the cross section of electrode 78A therein is substantially square. As shown in FIGS. 26B and 26C, the shape of the cross section of the electrode 78A is not limited. Further, the shape of the cross section of the hollow body 83 is also not limited to the example shown in the drawing.

The plasma generation unit 82 can be configured such that the axis of the electrode 78A coincides with the central axis of the hollow body 83. Thus, the plasma generated from the electrode 78A can be stably guided to the liquid level LS.

It is to be noted that the storage part 60A shown in FIG. 25 has a tapered shape with a wall surface tapered downward. The shape of the storage part is, however, not limited to the example shown in FIG. 25, and may be, for example, a cylinder or the like. In addition, the storage part has only to have a material and a thickness such that the vibration of the misting unit can be propagated to the dispersion liquid 63. The same applies to the shape, material, and thickness of the storage parts in according to the other embodiments described above.

### Eighth Embodiment: Modification Example 1

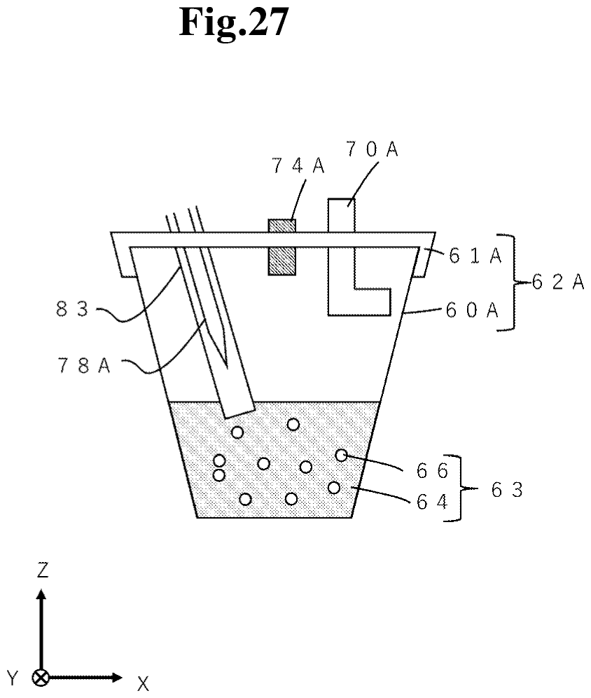

FIG. 27 is a schematic diagram showing an example of a mist generator 90 according to Modification Example 1 of the eighth embodiment. The illustration of the plug 84 and gas introduction part 85 is omitted in the drawing. The hollow body 83 and the electrode 78A according to the present modification example are placed to be inclined with respect to the liquid level. The hollow body 83 and the electrode 78A may be placed to be perpendicular or inclined with respect to the liquid level of the dispersion liquid 63.

### Eighth Embodiment: Modification Example 2

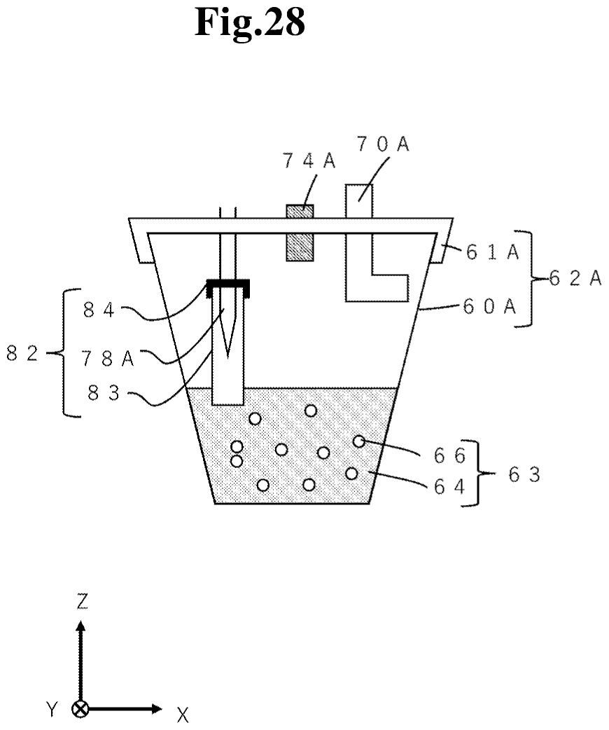

FIG. 28 is a schematic diagram showing an example of a mist generator 90 according to Modification Example 2 of the eighth embodiment. The hollow body 83 according to the present modification example has an upper end located below the lid part 61A. More specifically, the whole hollow body 83 is located in storage part 60A.

When the tip of the electrode 78A is housed inside the hollow body 83, with the lower end of the hollow body 83 located below the liquid level of the dispersion liquid 63, the dispersion liquid 63 can be irradiated stably with the plasma generated from the tip. Also in the present modification example, the plasma generation unit 82 may include the gas introduction part 85.

### Eighth Embodiment: Modification Example 3

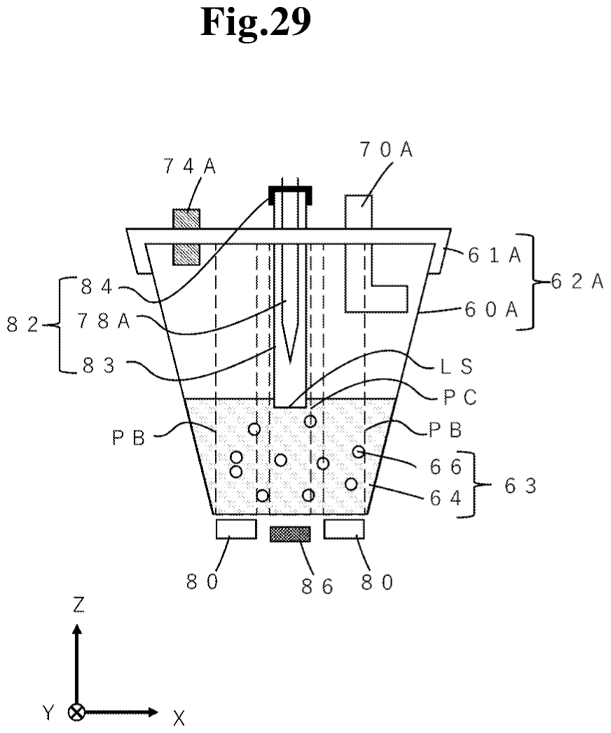

FIG. 29 is a schematic diagram showing an example of a mist generator 90 according to Modification Example 3 of the eighth embodiment. The mist generator 90 according to the present modification example includes a ground electrode 86. The ground electrode 86, placed under the container 62A, functions as a ground electrode for a voltage applied to the electrode 78A.

The region in a predetermined range above the ground electrode 86 in the container 62A is defined as a ground upper region PC. More specifically, the ground upper region PC is a region immediately above the ground electrode 86. For example, assuming that the upper end of the ground electrode 86 extends to the bottom surface of the container 62A, the ground upper region PC is a region in the storage part 60A, which stands, with a bottom surface within a predetermined range from the upper end of the ground electrode 86, directly above from the bottom surface to the lid part 61A. The electrode 78A is placed such that at least the tip thereof is located in the ground upper region PC.

The plasma emitted from the tip of the electrode 78A is guided toward the ground electrode 86. The tip of the electrode 78A is configured to be located immediately above the ground electrode 86, thereby allowing the plasma to be appropriately guided to the liquid level LS. More specifically, the particles 66 can be more efficiently dispersed.

In addition, the region immediately above the misting unit 80 in the container 62A is defined as a misting unit upper region PB. The misting unit 80 according to the present modification is, for example, an ultrasonic vibrator. Driving the misting unit 80 tends to cause the liquid level of the misting unit upper region PB to wave. The hollow body 83 according to the present modification example is placed at a position excluding the misting unit upper region PB, for reducing the influence of the waving liquid level on the plasma. More specifically, hollow body 83 is provided at a position excluding the misting unit upper region PB, which is a region in a predetermined range above the misting unit 80.

It is to be noted that the hollow body 83 according to the present modification example may be placed to be inclined with respect to the liquid level, as with the hollow body 83 illustrated in FIG. 27. The lower end of the hollow body 83 may be placed at a position excluding the misting unit upper region PB. This configuration allows the dispersion liquid 63 to be stably irradiated with the plasma, thereby allowing the dispersibility of the particles 66 in the dispersion liquid 63 to be further improved.

Additionally, the mist generator 90 according to the eighth embodiment can be configured such that the supply direction of the gas fed from the gas supply opening of the gas supply unit 70A is different from the direction of gravitational force, as in the other embodiments described above. For example, the angle made by the supply direction of the gas fed from the gas supply opening and the direction of gravitational force in which gravity acts may be 90 degrees or more and 150 degrees or less. In addition, the discharge opening 76 is preferably above the gas supply opening 72 as shown in FIG. 25, for easily discharging the generated mist from the storage part 60.

### REFERENCE SIGNS LIST

1 thin film manufacturing device
10 first chamber
10A⋅10B air-sealing part
12 second chamber
12A-12B air-sealing part
12C duct
20A⋅20B mist generation unit
21A⋅21B duct
22A⋅22B mist supply unit
23A⋅23B temperature controller
24A⋅24B electrode
25A⋅25B top board
27A⋅27B substrate temperature control unit
27C temperature-controlling plate
28 temperature control unit
30 exhaust control unit
30A duct
40 high-voltage pulse power supply unit
40A variable direct-current power supply
40B high-voltage pulse generation unit
40Ba pulse generation circuit section
40Bb boosting circuit section
50 drying unit
60⋅60A⋅60B⋅60C storage part
61⋅61A⋅61B⋅61C lid part
62⋅62A⋅62B⋅62C container
70A⋅70B⋅70C⋅70D⋅70E⋅70F⋅70G⋅70H⋅70I⋅70J gas supply unit
72⋅72A⋅72B⋅72C⋅72D⋅72E⋅72F⋅72G⋅72H⋅72I⋅72J gas supply opening
74⋅74A⋅74B⋅74C⋅74D⋅74E⋅74F discharge unit
76⋅76A⋅76B⋅76C⋅76D⋅76E1⋅76E2⋅76F1⋅76F2 discharge opening
78⋅8A⋅78B⋅78C electrode
79⋅79A⋅79B⋅79C tip
80 misting unit
81 plate-shaped member
82 plasma generation unit
83 hollow body
84 plug
85 gas introduction part
86 ground electrode
90 mist generator
91 external container
94 partition
96 storage space
98 empty space
100 main control unit
270 base
271A introduction port
271B exhaust port
272 spacer
274 plate
274A ejection hole
274B suction hole
275 substrate temperature controller
Cg⋅Cp dielectric
Cg1⋅Cp1 quartz tube
CR1⋅CR2⋅CR3⋅CR4 roller
Dh aperture
Dt distance
EG⋅EP⋅EP1⋅EP2 electrode
EQ1⋅EQ2 mount
ES1⋅ES2 edge sensor
FS substrate
La⋅Lb⋅Lc interval
LS liquid level
Mgs mist gas
PA region
PB misting unit upper region
PC ground upper region
RL1 supply roll
RL2 collection roll
Sfa Sfb Sfc inner wall
SN aperture
TB1⋅TB2 air turn bar
Tu time
Vo1⋅Vo2 voltage
WD working distance
φa outer diameter
φb inner diameter

1. A mist generator comprising:
a container that stores a liquid;
a gas supply unit that supplies a first gas from a gas supply opening into the container; and
an electrode that generates plasma between the electrode and the liquid,
wherein a supply direction of the first gas fed from the gas supply opening of the gas supply unit is different from a direction in which gravity acts.

2. A mist generator comprising:
a container that stores a liquid;
a gas supply unit that supplies a first gas from a gas supply opening into the container; and
an electrode that generates plasma between the electrode and the liquid,
wherein the gas supply opening of the gas supply unit does not face a liquid level.

3. The mist generator according to claim 2, comprising:
a member provided in the container,
wherein the member is disposed between the gas supply opening of the gas supply unit and the liquid level of the liquid.

4. The mist generator according to claim 3,
wherein the member has a plate shape.

5. A mist generator comprising:
a container that stores a liquid;
a gas supply unit that supplies a first gas from a gas supply opening into the container; and
an electrode that generates plasma between the electrode and the liquid,
wherein the gas supply unit supplies the first gas from the gas supply opening such that a liquid level of the liquid is not brought into contact with the electrode.

6. The mist generator according to claim 1, comprising:
a misting unit that turns the liquid into a mist.

7. The mist generator according to claim 6,
wherein the misting unit is an ultrasonic vibrator.

8. The mist generator according to claim 1,
wherein an angle made by the supply direction of the first gas fed from the gas supply opening of the gas supply unit and a direction of gravitational force in which gravity acts is 90 degrees to 150 degrees.

9. A mist generator comprising:
a container that stores a liquid;
a gas supply unit that supplies a first gas from a gas supply opening into the container; and
a plasma generation unit including an electrode that generates plasma between the electrode and a liquid level of the liquid, and a hollow body surrounding the electrode,
wherein one tip of the hollow body is located below the liquid level of the liquid.

10. The mist generator according to claim 9, wherein the electrode is provided at a position where a tip of the electrode on a liquid level side is not in contact with the liquid level of the liquid.

11. The mist generator according to claim 9, wherein the plasma generation unit comprises a gas introduction part that introduces a second gas into the hollow body.

12. The mist generator according to claim 9, wherein the electrode is disposed in the hollow body such that an axis of the electrode coincides with a central axis of the hollow body.

13. The mist generator according to claim 9, further comprising a misting unit that generates a mist of the liquid.

14. The mist generator according to claim 13, wherein the misting unit is an ultrasonic vibrator.

15. The mist generator according to claim 13, wherein the hollow body is provided at a position excluding a misting unit upper region that is a region in a predetermined range above the misting unit in the container.

16. The mist generator according to claim 11, wherein the second gas is a gas containing at least one of helium, xenon, and argon.

17. The mist generator according to claim 9, comprising
a ground electrode for a voltage applied to the electrode below the container,
wherein the electrode is provided so as to be located in a ground upper region that is a region in a predetermined range above the ground electrode in the container.

18. The mist generator according to claim 9, wherein a supply direction of the first gas fed from the gas supply opening of the gas supply unit is different from a direction of gravitational force.

19. The mist generator according to claim 18,
wherein an angle made by the supply direction of the first gas fed from the gas supply opening of the gas supply unit and the direction of gravitational force in which gravity acts is 90 degrees to 150 degrees.

20. The mist generator according to claim 1, comprising
a discharge unit that discharges the liquid turned into a mist, from the container.

21. The mist generator according to claim 20,
wherein the container includes a storage part with an opening and a lid part that covers the opening, and
the electrode, the gas supply unit, and the discharge unit are inserted through the lid part and disposed.

22. The mist generator according to claim 20,
wherein an angle made by a discharge direction of the first gas discharged from a discharge opening of the discharge unit and the direction of gravitational force in which gravity acts is 120 degrees to 180 degrees.

23. The mist generator according to claim 22,
wherein an angle made by the supply direction of the first gas fed from the gas supply opening of the gas supply unit and the discharge direction of the first gas discharged from the discharge opening is 30 degrees to 150 degrees.

24. The mist generator according to claim 22,
wherein the discharge unit has two or more discharge openings.

25. The mist generator according to claim 22,
wherein the gas supply opening is placed below the discharge opening.

26. The mist generator according to claim 1, comprising
two or more gas supply units.

27. The mist generator according to claim 1, comprising
two or more gas supply openings.

28. The mist generator according to claim 1, comprising
two or more electrodes.

29. The mist generator according to claim 1,
wherein the container is made of a plastic or a metal.

30. The mist generator according to claim 1,
wherein a tip of the electrode has a spherical shape.

31. The mist generator according to claim 1,
wherein a tip of the electrode has a needle shape.

32. The mist generator according to claim 1,
wherein the first gas is any one of helium, argon, and xenon.

33. The mist generator according to claim 1, comprising
a power supply unit that applies a voltage to the electrode,
wherein the power supply unit applies a voltage at a frequency of 0.1 Hz or higher and 50 kHz or lower.

34. The mist generator according to claim 33,
wherein the power supply unit applies a voltage of 21 kV or higher.

35. The mist generator according to claim 33,
wherein the power supply unit applies a voltage to generate an electric field of 1.1-10⁶ V/m or more on the electrode.

36. The mist generator according to claim 1,
wherein the liquid is a dispersion liquid including particles and a dispersion medium.

37. The mist generator according to claim 36,
wherein the dispersion medium includes water.

38. The mist generator according to claim 36,
wherein the particles are inorganic oxides.

39. The mist generator according to claim 36,
wherein the particles contain any one or more of a silicon dioxide, a zirconium oxide, an indium oxide, a zinc oxide, a tin oxide, a titanium oxide, an indium tin oxide, a potassium tantalate, a tantalum oxide, an aluminum oxide, a magnesium oxide, a hafnium oxide, and a tungsten oxide.

40. The mist generator according to claim 36,
wherein the particles have an average particle size of 5 nm to 1000 nm.

41. The mist generator according to claim 36,
wherein the particles included in the dispersion liquid has a concentration of 0.001% by mass to 80% by mass.

42. A thin film manufacturing device for forming a film on a substrate, the thin film manufacturing device comprising:
the device according to claim 1; and
a mist supply unit that supplies the liquid turned into a mist onto a predetermined substrate.

43. A thin film manufacturing method for forming a film on a substrate, the thin film manufacturing method comprising:
a step of using the mist generator according to claim 1 to turn the liquid into a mist; and
a step of supplying the liquid turned into the mist to a predetermined substrate.
